(19) United States
(12) Patent Application Publication
(10) Pub. No.: US 2022/0069547 A1
(43) Pub. Date: Mar. 3, 2022

(54) SEMICONDUCTOR LASER ELEMENT

(71) Applicant: ROHM CO., LTD., Kyoto (JP)

(72) Inventors: Yuki HIROKAWA, Kyoto (JP); Yuji ISHIDA, Kyoto (JP); Yoshio NISHIMOTO, Kyoto (JP)

(73) Assignee: ROHM CO., LTD., Kyoto (JP)

(21) Appl. No.: 17/417,278

(22) PCT Filed: Oct. 30, 2019
(86) PCT No.: PCT/JP2019/042637

§ 371 Date: Jun. 22, 2021

(30) Foreign Application Priority Data
Dec. 28, 2018 (JP) 2018-248029
Feb. 18, 2019 (JP) 2019-026821

(51) Int. Cl. H01S 5/343; H01S 5/223; H01S 5/06; H01S 5/042; H01S 5/02

(52) U.S. Cl. CPC H01S 5/3434; H01S 5/2231; H01S 5/0202; H01S 5/04256; H01S 5/0612

(57) ABSTRACT

A semiconductor laser element includes a semiconductor laminated structure that has a substrate, an n type cladding layer disposed at a front surface side of the substrate, an active layer disposed at an opposite side of the n type cladding layer to the substrate, and p type cladding layers disposed at an opposite side of the active layer to the n type cladding layer. The active layer includes a quantum well layer having a tensile strain for generating TM mode oscillation and the n type cladding layer and the p type cladding layers are respectively constituted of AlGaAs layers.

### TECHNICAL FIELD

The present invention relates to a semiconductor laser element.

### BACKGROUND ART

To increase a storage capacity of a hard disc drive (HDD), signals must be written into microscopic regions of the disc. Although a thermally stable recording medium is required to record signals into microscopic regions while securing thermal stability of the signals, this gives to rise to a dilemma that a strong magnetic field is required for writing. Now that recording density is reaching saturation with the existing GMR (giant magneto resistance) method, realization of a “thermally assisted recording” method is being desired. The “thermally assisted recording” method is a method in which writing is performed while temporarily weakening a force that holds a magnetic field by using a laser diode (semiconductor laser element) as a heat source.

### CITATION LIST

### Patent Literature

Patent Literature 1: Japanese Patent Application Publication No. 7-111367

Patent Literature 2: Japanese Patent Application Publication No. 2011-187149

### SUMMARY OF INVENTION

### Technical Problem

To provide compatibility with the existing slider making process, a semiconductor laser element used in a recording device of the “thermally assisted recording” method, unlike a semiconductor laser element for a conventional optical pickup, is required to provide high output power with small chip size.

Also, since there is a limit to a mounting space of the semiconductor laser element, there arise cases where, depending on optical system design, not just TE (transverse electric) polarized light that is common with conventional semiconductor laser elements, but TM (transverse magnetic) polarized light must also be realized. For example, in Patent Literature 2 mentioned above, it is disclosed that a laser diode used in a thermally assisted magnetic recording head disclosed in Patent Literature 2 is preferably a chip that generates polarized light of TM mode.

An object of the present invention is to provide a semiconductor laser element with which TM mode oscillation can be obtained and is high in output power as well as high in reliability.

### Solution to Problem

A preferred embodiment of the present invention provides a semiconductor laser element being a semiconductor laser element that oscillates in TM mode and including a semiconductor laminated structure that has a substrate, an n type cladding layer disposed at a front surface side of the substrate, an active layer disposed at an opposite side of the n type cladding layer to the substrate, and a p type cladding layer disposed at an opposite side of the active layer to the n type cladding layer, and where the active layer includes a quantum well layer having a tensile strain for generating TM mode oscillation and the n type cladding layer and the p type cladding layer are respectively constituted of AlGaAs layers.

With this arrangement, the quantum well layer has the tensile strain for generating the TM mode oscillation and therefore, the semiconductor laser element can be made to oscillate in the TM mode.

Also, with this arrangement, the n type cladding layer and the p type cladding layer are respectively constituted of AlGaAs layers. AlGaAs is low in resistance in comparison to InGaAlP that is generally used as cladding layers in a semiconductor laser element that oscillates in the TM mode. Therefore, with the present arrangement, serial resistance can be decreased in comparison to the semiconductor laser element with which the cladding layers are constituted of InGaAlP layers. Heat generation can thereby be suppressed in comparison to the semiconductor laser element with which the cladding layers are constituted of InGaAlP layers and therefore, a semiconductor laser element of high output power and high reliability can be obtained.

With the preferred embodiment of the present invention, an end surface window structure that enlarges a bandgap of the active layer is formed at an end surface portion of a laser resonator. With this arrangement, absorption of laser light at the end surface portion of the laser resonator can be suppressed. Catastrophic optical damage (COD) can thereby be suppressed and life extension of the semiconductor laser element can thus be achieved.

With the preferred embodiment of the present invention, the active layer includes a plurality of the quantum well layers and a barrier layer sandwiched by the quantum well layers that are adjacent and having a compressive strain.

With the preferred embodiment of the present invention, the substrate is constituted of a GaAs substrate and the quantum well layer is constituted of a GaAsP layer.

With the preferred embodiment of the present invention, the substrate is constituted of a GaAs substrate and the barrier layer is constituted of an InAlGaAs layer.

With the preferred embodiment of the present invention, a current constriction layer that is formed at an opposite side to the active layer with respect to the p type cladding layer and is arranged to constrict current flowing through the active layer is further included.

With the preferred embodiment of the present invention, a front surface of the p type cladding layer at an opposite side to the active layer as viewed in a resonator length direction includes a flat portion that is parallel to a front surface of the active layer and inclined surfaces that are respectively formed at both sides of the flat portion and are inclined with respect to the front surface of the active layer, a p type GaAs capping layer is formed on the flat portion of the p type cladding layer, and the current constriction layer is formed such as to cover the inclined surfaces of the p type cladding layer and a side surface of the p type GaAs capping layer.

With the preferred embodiment of the present invention, the current constriction layer is constituted of a laminated film of an AlGaAs layer and a GaAs layer formed on the AlGaAs layer.

With the preferred embodiment of the present invention, a GaAs contact layer that is formed such as to cover a front surface of the current constricting layer and a front surface of the p type GaAs capping layer, a p side electrode that is formed on the GaAs contact layer, and an N side electrode that is formed on a rear surface of the substrate are included.

With the preferred embodiment of the present invention, the semiconductor laminated structure has a pair of end surfaces that constitute resonance surfaces of the laser resonator, a pair of side surfaces, and first separating groove marks that are formed in upper edge regions of the pair of side surfaces continuous to a front surface of the semiconductor laminated structure.

With the preferred embodiment of the present invention, the first separating groove marks are formed across an entire length direction of the semiconductor laminated structure.

With the preferred embodiment of the present invention, the semiconductor laminated structure further has second separating groove marks that are formed in lower edge regions of the pair of side surfaces that are continuous to a rear surface of the semiconductor laminated structure.

With the preferred embodiment of the present invention, the second separating groove marks are formed in length direction intermediate portions of the semiconductor laminated structure.

A preferred embodiment of the present invention provides a semiconductor laser element including a semiconductor laminated structure that has a substrate, an n type cladding layer disposed at a front surface side of the substrate, an active layer disposed at an opposite side to the substrate with respect to the active layer, and a p type cladding layer disposed at an opposite side to the n type cladding layer with respect to the active layer, a semiconductor laser p side electrode that is formed on portion of a front surface of the semiconductor laminated structure at an opposite side to the substrate side, an insulating film that is formed on a portion of the front surface of the semiconductor laminated structure, a heater that is formed on the insulating film, and a first heater electrode connected to one end of the heater and a second heater electrode connected to another end of the heater that are formed on the insulating film.

With this arrangement, the heater is included and therefore, by driving and controlling the heater, a temperature of the semiconductor laser element can be controlled. Therefore, for example, the temperature of the semiconductor laser element can be controlled such that the temperature of the semiconductor laser element is substantially fixed.

With the preferred embodiment of the present invention, a main portion of the first heater electrode and a main portion of the second heater electrode are each disposed at an opposite side to the semiconductor laser p side electrode with respect to the heater and the main portion of the first heater electrode, the main portion of the second heater electrode, and the semiconductor laser p side electrode respectively have portions thicker than a thickness of the heater.

With the preferred embodiment of the present invention, the portions thicker than the thickness of the heater each have a thickness not less than 5 times the thickness of the heater.

With the preferred embodiment of the present invention, the p type cladding layer has a ridge portion of rectilinear shape and the semiconductor laser p side electrode is formed in a region that includes the ridge portion in plan view.

With the preferred embodiment of the present invention, the heater is disposed in parallel to the ridge portion in plan view.

With the preferred embodiment of the present invention, the heater extends rectilinearly in plan view.

With the preferred embodiment of the present invention, the heater extends in a meandering shape in plan view.

With the preferred embodiment of the present invention, the heater is constituted of a laminated film of a Ti film formed on the insulating film and a Pt film laminated on the Ti film.

A preferred embodiment of the present invention provides a semiconductor laser element including a semiconductor laminated structure that has a substrate, an n type cladding layer disposed at a front surface side of the substrate, an active layer disposed at an opposite side to the substrate with respect to the active layer, and a p type cladding layer disposed at an opposite side to the n type cladding layer with respect to the active layer and where a region separating groove that separates a main semiconductor laser region used as a main semiconductor laser and a heat source semiconductor laser region used as a heat source semiconductor laser is formed on a front surface of the semiconductor laminated structure at an opposite side to the substrate side, a first p side electrode for the main semiconductor laser is formed on the front surface of the semiconductor laminated structure in the main semiconductor laser region, and a second p side electrode for the heat source semiconductor laser is formed on the front surface of the semiconductor laminated structure in the heat source semiconductor laser region.

With this arrangement, the main semiconductor laser and the heat source semiconductor laser are included and therefore, by driving and controlling the heat source semiconductor laser, a temperature of the main semiconductor laser (semiconductor laser element) can be controlled. Therefore, for example, the temperature of the semiconductor laser element can be controlled such that the temperature of the main semiconductor laser is substantially fixed.

With the preferred embodiment of the present invention, the region separating groove reaches the substrate.

With the preferred embodiment of the present invention, an n side electrode for the main semiconductor laser and the heat source semiconductor laser is formed on a rear surface of the semiconductor laminated structure at an opposite side to the front surface.

With the preferred embodiment of the present invention, in the main semiconductor laser region, the p type cladding layer has a first ridge portion of rectilinear shape and in the heat source semiconductor laser region, the p type cladding layer has a second ridge portion of rectilinear shape.

With the preferred embodiment of the present invention, the second ridge portion is constituted of a plurality of rectangular ridge portions that are disposed rectilinearly at intervals in plan view.

The aforementioned as well as yet other objects, features, and effects of the present invention will be made clear by the following description of the preferred embodiments, with reference to the accompanying drawings.

### BRIEF DESCRIPTION OF DRAWINGS

FIG. 1 is a perspective view of an outer appearance of a semiconductor laser element according to a first preferred embodiment of the present invention.

FIG. 2 is a front view of the semiconductor laser element of FIG. 1.

FIG. 3 is a plan view of the semiconductor laser element of FIG. 1.

FIG. 4 is a bottom view of the semiconductor laser element of FIG. 1.

FIG. 5 is an illustrative sectional view taken along line V-V of FIG. 3.

FIG. 6 is an illustrative sectional view taken along line VI-VI of FIG. 3.

FIG. 7 is an illustrative sectional view for describing the arrangement of an active layer of the semiconductor laser element of FIG. 1.

FIG. 8 is an illustrative sectional view of a manufacturing process of the semiconductor laser element.

FIG. 9 is an illustrative sectional view of the manufacturing process of the semiconductor laser element.

FIG. 10 is an illustrative sectional view of the manufacturing process of the semiconductor laser element.

FIG. 11 is an illustrative sectional view of the manufacturing process of the semiconductor laser element.

FIG. 12 is an illustrative sectional view of the manufacturing process of the semiconductor laser element.

FIG. 13 is a plan view of the manufacturing process of the semiconductor laser element.

FIG. 14 is an illustrative plan view of a portion of a wafer in a state where a plurality of individual elements are formed.

FIG. 15 is an illustrative plan view of first separating grooves formed in a front surface of a semiconductor laminated structure.

FIG. 16A is a partially enlarged sectional view taken along line XVI-XVI of FIG. 15.

FIG. 16B is a sectional view of a modification example of a cross-sectional shape of a first separating groove.

FIG. 17 is an illustrative perspective view of a bar body obtained by primary cleavage.

FIG. 18 is an illustrative bottom view of second separating grooves formed in a rear surface of the bar body.

FIG. 19 is an illustrative perspective view of individual elements obtained from the bar body by secondary cleavage.

FIG. 20A is a graph of optical output power vs. injection current characteristics of the first preferred embodiment.

FIG. 20B is a graph of optical output power vs. injection current characteristics of a comparative example.

FIG. 21 is an illustrative sectional view of a semiconductor laser element according to a second preferred embodiment of the present invention and is a sectional view corresponding to the section plane of FIG. 6.

FIG. 22 is an illustrative sectional view of a semiconductor laser element according to a third preferred embodiment of the present invention and is a sectional view corresponding to the section plane of FIG. 6.

FIG. 23 is an illustrative perspective view of an outer appearance of a semiconductor laser element according to a fourth preferred embodiment of the present invention.

FIG. 24 is an illustrative plan view of the semiconductor laser element of FIG. 23.

FIG. 25 is an illustrative sectional view taken along line XXV-XXV of FIG. 24.

FIG. 26A is an illustrative plan view of an example of a manufacturing process of the semiconductor laser element of FIG. 23.

FIG. 26B is an illustrative plan view of a step subsequent to that of FIG. 26A.

FIG. 26C is an illustrative plan view of a step subsequent to that of FIG. 26B.

FIG. 26D is an illustrative plan view of a step subsequent to that of FIG. 26C.

FIG. 26E is an illustrative plan view of a step subsequent to that of FIG. 26D.

FIG. 26F is an illustrative plan view of a step subsequent to that of FIG. 26E.

FIG. 27A is an illustrative sectional view of the example of the manufacturing process of the semiconductor laser element of FIG. 23.

FIG. 27B is an illustrative sectional view of a step subsequent to that of FIG. 27A.

FIG. 27C is an illustrative sectional view of a step subsequent to that of FIG. 27B.

FIG. 27D is an illustrative sectional view of a step subsequent to that of FIG. 27C.

FIG. 27E is an illustrative sectional view of a step subsequent to that of FIG. 27D.

FIG. 27F is an illustrative sectional view of a step subsequent to that of FIG. 27E.

FIG. 28 is an illustrative plan view of another example of a heater.

FIG. 29 is an illustrative perspective view of an outer appearance of a semiconductor laser element according to a fifth preferred embodiment of the present invention.

FIG. 30 is an illustrative plan view of the semiconductor laser element of FIG. 29.

FIG. 31 is an illustrative sectional view taken along line XXXI-XXXI of FIG. 30.

FIG. 32 is an illustrative plan view of another example of ridges formed in a heat source semiconductor laser region.

### DESCRIPTION OF EMBODIMENTS

### [1] First Embodiment

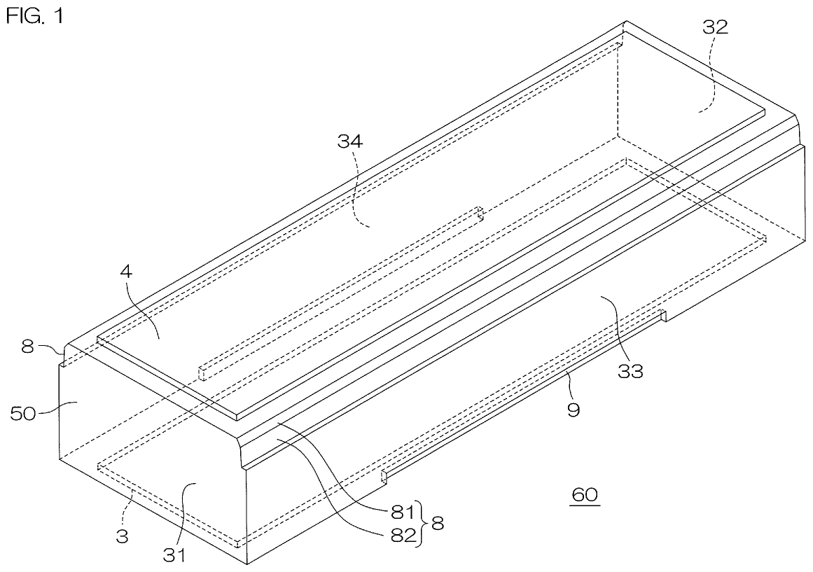

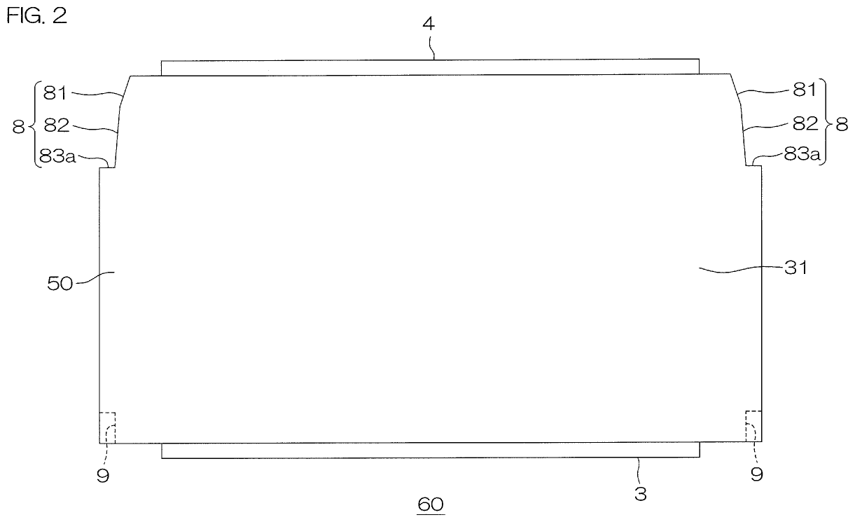

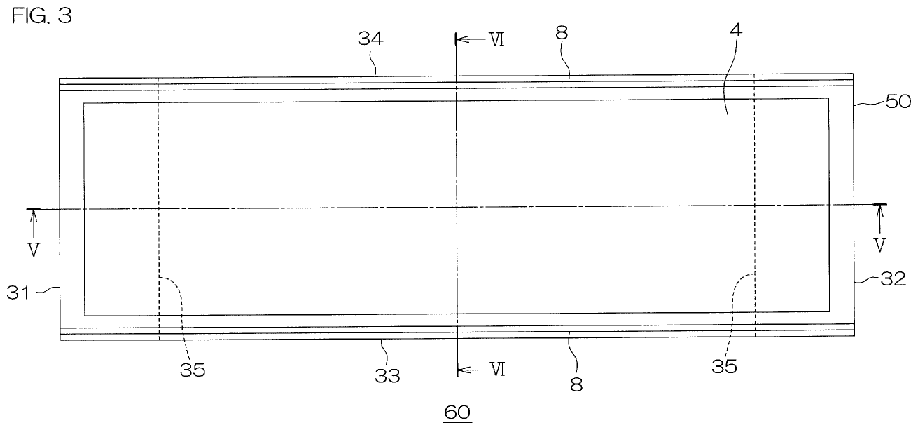

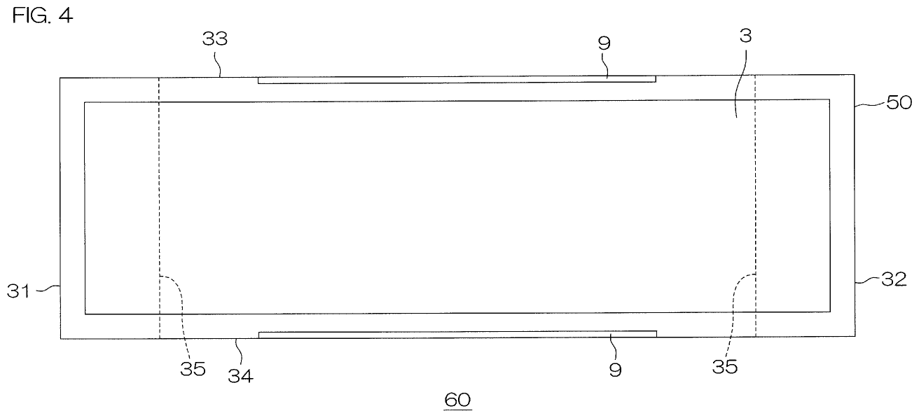

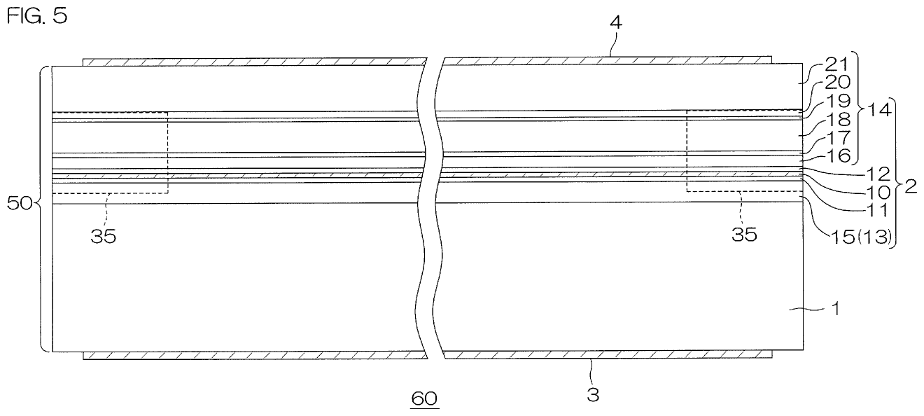

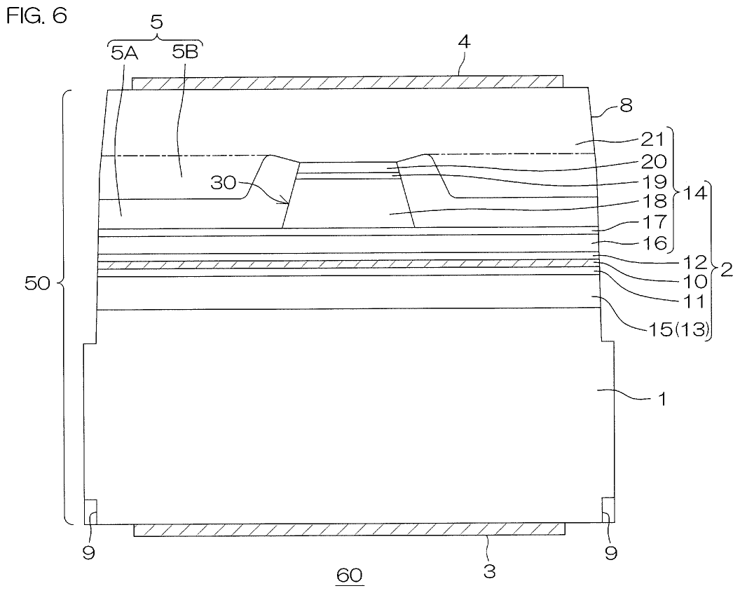

FIG. 1 is a perspective view of an outer appearance of a semiconductor laser element according to a first preferred embodiment of the present invention. FIG. 2 is a front view of the semiconductor laser element of FIG. 1. FIG. 3 is a plan view of the semiconductor laser element of FIG. 1. FIG. 4 is a bottom view of the semiconductor laser element of FIG. 1. FIG. 5 is an illustrative sectional view taken along line V-V of FIG. 3. FIG. 6 is an illustrative sectional view taken along line VI-VI of FIG. 3.

This semiconductor laser element 60 is of a Fabry-Perot type that includes a substrate 1, a semiconductor laminated structure (semiconductor laminated structure in the narrow sense) 2 that is formed by crystal growth on the substrate 1, an n side electrode 3 that is formed such as to contact a rear surface (surface at an opposite side to the semiconductor laminated structure 2) of the substrate 1, and a p side electrode 4 that is formed such as to contact a front surface of the semiconductor laminated structure 2.

In this preferred embodiment, the substrate 1 is constituted of a GaAs monocrystalline substrate. A plane orientation of a front surface of the GaAs substrate 1 is a (100) plane. Respective layers forming the semiconductor laminated structure 2 are epitaxially grown with respect to the substrate 1. Epitaxial growth refers to crystal growth in a state of maintaining continuity of lattice from a base layer. Lattice mismatch with the base layer is absorbed by strain of the lattice of the layer that is crystal-grown and continuity of the lattice is maintained at an interface with the base layer.

The semiconductor laminated structure 2 includes an active layer 10, an n side guide layer 11, a p side guide layer 12, an n type semiconductor layer 13, and a p type semiconductor layer 14. The n type semiconductor layer 13 is disposed at a substrate 1 side with respect to the active layer 10 and the p type semiconductor layer 14 is disposed at a p side electrode 4 side with respect to the active layer 10.

The n side guide layer 11 is disposed between the n type semiconductor layer 13 and the active layer 10 and the p side guide layer 12 is disposed between the active layer 10 and the p type semiconductor layer 14. A double heterojunction is thereby formed. Into the active layer 10, electrons are injected from the n type semiconductor layer 13 via the n side guide layer 11 and holes are injected from the p type semiconductor layer 14 via the p side guide layer 12. Light is arranged to be generated by these recombining in the active layer 10.

The n type semiconductor layer 13 is arranged by forming an n type AlGaAs cladding layer 15 (for example, of 20000 Å to 35000 Å thickness) on the substrate 1. The n type AlGaAs cladding layer 15 is constituted, for example, of an AlₓGa₍₁₋ₓ₎As (0≤x≤1) layer.

On the other hand, the p type semiconductor layer 14 is arranged by laminating a first p type AlGaAs cladding layer 16 (for example, of 1000 Å to 2000 Å thickness), a p type InGaP etching stop layer 17 (for example, of 50 Å to 300 Å thickness), a second p type AlGaAs cladding layer 18 (for example, of 8000 Å to 12000 Å thickness), a p type InGaP etching stop layer 19 (for example, of 50 Å to 300 Å thickness), a p type GaAs capping layer 20 (for example, of 1000 Å to 3000 Å thickness), and a p type GaAs contact layer 21 (for example, of 30000 Å to 60000 Å thickness) on the p side guide layer 12.

The first p type AlGaAs cladding layer 16 is constituted, for example, of an AlₓGa₍₁₋ₓ₎As (0≤x≤1) layer. The second p type AlGaAs cladding layer 18 is constituted, for example, of a p type AlₓGa₍₁₋ₓ₎As (0≤x≤1) layer (for example, of 8000 Å to 12000 Å thickness) formed on the p type InGaP etching stop layer 17.

The p type GaAs contact layer 21 is a low resistance layer for achieving ohmic contact with the p side electrode 4. The p type GaAs contact layer 21 is made a p type semiconductor layer by doping, for example, Be as a p type dopant into GaAs.

The n type cladding layer 15 and the first and second p type cladding layers 16 and 18 give rise to a carrier confinement effect of confining carriers (electrons and holes) in the active layer 10 and an optical confinement effect of confining light from the active layer 10 therebetween. The n type AlGaAs cladding layer 15 is made an n type semiconductor layer by doping, for example, Si as an n type dopant into AlGaAs. The first and second p type AlGaAs cladding layers 16 and 18 are made p type semiconductor layers by doping, for example, Be as a p type dopant into AlGaAs.

The n type AlGaAs cladding layer 15 is wider in bandgap than the n side guide layer 11 and the first and second p type AlGaAs cladding layers 16 and 18 are wider in bandgap than the p side guide layer 12. Satisfactory carrier confinement and optical confinement can thereby be achieved to realize a semiconductor laser element of high efficiency.

To make life extension and high output power possible, it is important to suppress catastrophic optical damage. It is therefore preferable to make end surface window structures 35 that enlarge a bandgap of the active layer 10 by diffusing an impurity such as zinc, etc., in laser resonator end surface portions as shall be described later.

The n side guide layer 11 is constituted of an AlGaAs layer (for example, of 200 Å to 500 Å thickness) and is arranged by laminating on the n type semiconductor layer 13. The p side guide layer 12 is constituted of AlGaAs (for example, of 200 Å to 500 Å thickness) and is arranged by laminating on the active layer 10. The n side guide layer and the p side guide layer 12 are respectively constituted, for example, of AlₓGa₍₁₋ₓ₎As (0≤x≤1) layers.

The n side AlGaAs guide layer 11 and the p side AlGaAs guide layer 12 are semiconductor layers that give rise to an optical confinement effect in the active layer 10 and, together with the cladding layers 15, 16, and 18, form a structure that confines carriers in the active layer 10. An arrangement is thereby made such as to increase efficiency of recombination of electrons and holes in the active layer 10.

The active layer 10 has a multiple quantum well (MQW) structure and is a layer arranged to generate light by recombination of electrons and holes and amplify the generated light.

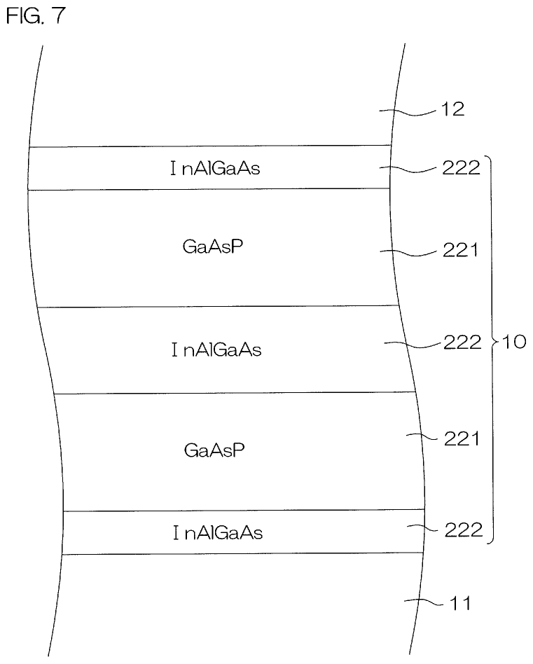

In this preferred embodiment, the active layer 10 has the multiple quantum well structure arranged by repeatedly laminating quantum well layers 221 constituted of undoped GaAsP layers (for example, of 60 Å to 120 Å thickness) and barrier layers 222 constituted of undoped InAlGaAs layers alternately in a plurality of cycles as shown in FIG. 7. In this preferred embodiment, the active layer 10 is constituted of a laminated film in which an (AlₓGa₍₁₋ₓ₎)_{(1-y)}In_{y}As barrier layer 222 (for example, of 20 Å to 90 Å thickness), a GaAs₍₁₋₁₎Pₓ quantum well layer 221 (for example, of 60 Å to 120 Å thickness), an (AlₓGa₍₁₋ₓ₎)_{(1-y)}In_{y}As barrier layer 222 (for example, of 40 Å to 100 Å thickness), a GaAs₍₁₋ₓ₎Pₓ quantum well layer 221 (for example, of 60 Å to 120 Å thickness), and an (AlₓGa₍₁₋ₓ₎)_{(1-y)}In_{y}As barrier layer 222 (for example, of 20 Å to 90 Å thickness) are laminated successively from a lower side.

A lattice constant of a GaAsP layer is smaller than a lattice constant of the GaAs substrate 1 and therefore, tensile stresses (tensile strains) are generated in the quantum well layers 221 that are constituted of GaAs₍₁₋ₓ₎Pₓ layers. The semiconductor laser element 60 is thereby made capable of oscillating in TM mode. In the present description, it shall be deemed that when a polarization ratio of output light of a semiconductor laser element becomes not less than 5 [dB], the semiconductor laser element is oscillating in the TM mode. Here, the polarization ratio is defined as polarization ratio=10 LOG (TM component optical output power/TE component optical output power) [dB]. Furthermore, in the TM mode, an electrical field is biased toward a direction perpendicular to a heterojunction surface.

On the other hand, a lattice constant of an InAlGaAs layer is greater than the lattice constant of the GaAs substrate 1 and therefore, compressive stresses (compressive strains) are generated in the barrier layers 222 that are constituted of (AlₓGa₍₁₋ₓ₎)_{(1-y)})In_{y}As layers. Thus, whereas tensile strains are generated in the quantum well layers 221, compressive strains are generated in the barrier layers 222 and therefore, strain of the active layer 10 as a whole is relaxed. Crystal degradation during energization is thereby suppressed and reliability of the semiconductor laser element can thus be improved.

As shown in FIG. 6, the second p type cladding layer 18, the p type etching stop layer 19, and the p type capping layer 20 inside the p type semiconductor layer 14 have portions thereof removed to form a rectilinear ridge 30. More specifically, portions of the second p type cladding layer 18, the p type etching stop layer 19, and the p type capping layer 20 are removed by etching to form the ridge 30 of substantially trapezoidal shape (mesa shape) in transverse sectional view. The second p type cladding layer 18 thus includes a flat portion at a width central portion that is parallel to a front surface of the active layer 10 and inclined surfaces inclining downward toward outer sides that are respectively formed both sides of the flat portion.

Current constriction layers (embedded layers) 5 (for example, of 8000 Å to 15000 Å thickness) are formed at side surfaces of the ridge 30. More specifically, side surfaces of the p type capping layer 20, side surfaces of the p type etching stop layer 19, exposed surfaces of the second p type cladding layer 18, and exposed surfaces of the p type etching stop layer 17 are covered by the current constriction layers 5. Exposed surfaces of the current constriction layers 5 and the p type capping layer 20 are covered by the contact layer 21.

Each current constriction layer 5 is constituted of a lower layer 5A formed on the p type etching stop layer 17 and an upper layer 5B formed on the lower layer. The lower layer 5A is constituted, for example, of an AlₓGa₍₁₋ₓ₎As layer (for example, of 5000 Å to 10000 Å thickness) and the upper layer 5B is constituted, for example, of a GaAs layer (for example, of 1500 Å to 7000 Å thickness). A boundary between the upper layer 5B of the current constriction layer 5 and the contact layer 21 is not clear and is therefore indicated by an alternate long and short dashed line.

The semiconductor laminated structure 2 has a pair of end surfaces (cleavage surfaces) 31 and 32 constituted of mirror surfaces formed by cleavage surfaces at both ends in a long direction of the ridge 30. This pair of end surfaces 31 and 32 are parallel to each other. A Fabry-Perot resonator having the pair of end surfaces 31 and 32 as resonator end surfaces is thus formed by the n side guide layer 11, the active layer 10, and the p side guide layer 12. That is, light generated in the active layer 10 is amplified by stimulated emission while reciprocating between the resonator end surfaces 31 and 32. A portion of the amplified light is taken out to the element exterior as laser light from the resonator end surfaces 31 and 32.

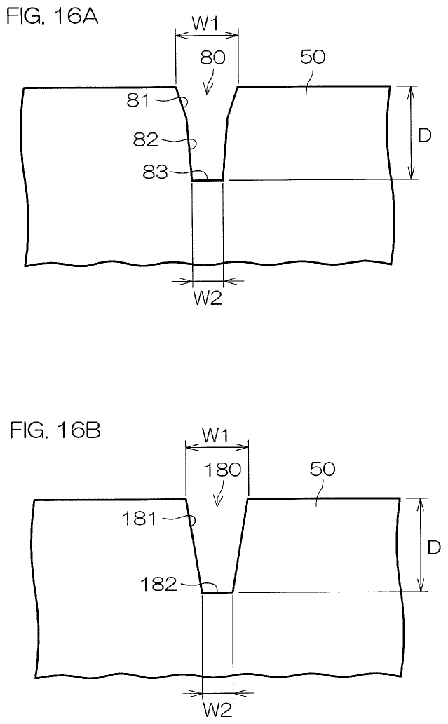

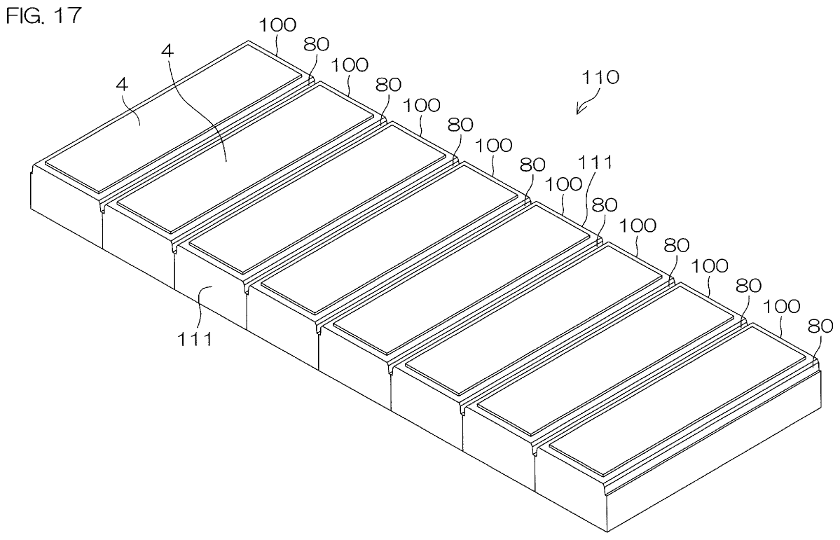

Also, a semiconductor laminated structure 50 (semiconductor laminated structure in the broad sense) that includes the substrate 1, the semiconductor laminated structure 2, and the current constriction layers 5 has a pair of side surfaces 33 and 34 that are parallel to the ridge 30. In upper edge regions at front surface sides of these pair of side surfaces 33 and 34, first separating groove marks 8 resulting from first separating grooves (first dividing guide grooves) 80 (see FIG. 15 and FIG. 16A) that are formed for cleaving and dividing the semiconductor laminated structure 50 from a wafer (to be accurate, a bar body 110 to be described later (see FIG. 17)) as an original substrate are formed across entireties in a length direction. The upper edge regions are regions continuous to a front surface of the semiconductor laminated structure 50 (front surface at the p type semiconductor layer 14 side). Also, the length direction is the long direction of the ridge 30 (resonator length direction). The semiconductor laminated structure 50 is an example of a semiconductor laminated structure of the present invention.

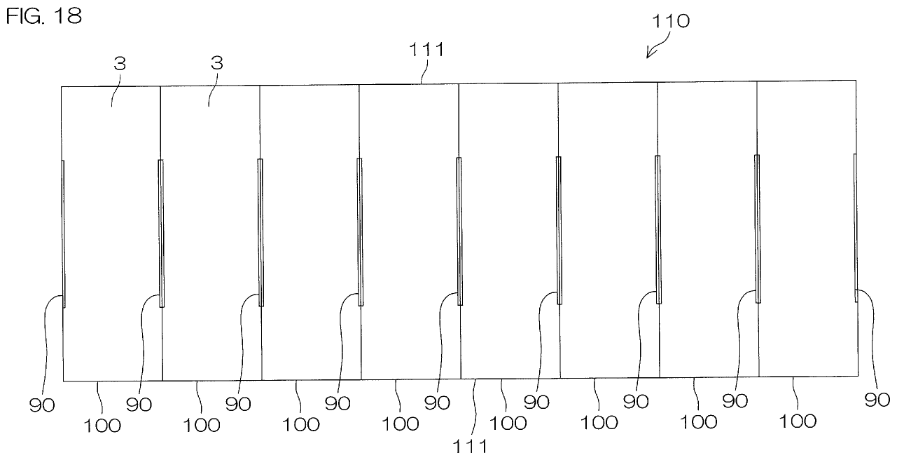

Further, in length direction intermediate portions of lower edge regions at rear surface sides of the pair of side surfaces 33 and 34, second separating groove marks 9 resulting from second separating grooves (second dividing guide grooves) 90 (see FIG. 18) that are formed for cleaving and dividing the semiconductor laminated structure 50 from the wafer (to be accurate, the bar body 110 to be described later (see FIG. 17)) as the original substrate are formed across entireties in the length direction. The lower edge regions are regions continuous to a rear surface of the substrate 1.

The n side electrode 3 is constituted, for example, of an AuGeNi/Ti/Au alloy and is in ohmic junction with the substrate 1 such that an AuGeNi side thereof is disposed at the substrate 1 side. The p side electrode 4 is constituted of a first electrode film formed on the p type contact layer 21 and a second electrode film formed on the first electrode film. The first electrode film is constituted, for example, of a Ti/Au alloy and is in ohmic junction with the p type contact layer 21 such that a Ti side thereof is disposed at the p type contact layer 21 side. The second electrode film is constituted, for example, of an Au plating.

As shown in FIG. 3, FIG. 4, and FIG. 5, the end surface window structures 35 that enlarge the bandgap of the active layer 10 are formed in the end surface portions of the resonator. These end surface window structures 35 are formed, for example, by diffusing zinc (Zn) in the end surface portions of the resonator.

Although unillustrated in FIG. 1 to FIG. 6, reflecting films arranged to protect the resonator end surfaces are formed at the resonator end surfaces.

With such an arrangement, by connecting the n side electrode 3 and the p side electrode 4 to a power supply and injecting electrons and holes from the n type semiconductor layer 13 and the p type semiconductor layer 14 into the active layer 10, recombination of electrons and holes inside the active layer 10 can be made to occur to generate light, for example, of an oscillation wavelength of not less than 780 nm and not more than 830 nm. This light is amplified by stimulated emission while reciprocating between the resonator end surfaces 31 and 32 and along the guide layers 11 and 12. A higher laser output power is thus taken out to the exterior from the resonator end surface 31 that is a laser emitting end surface.

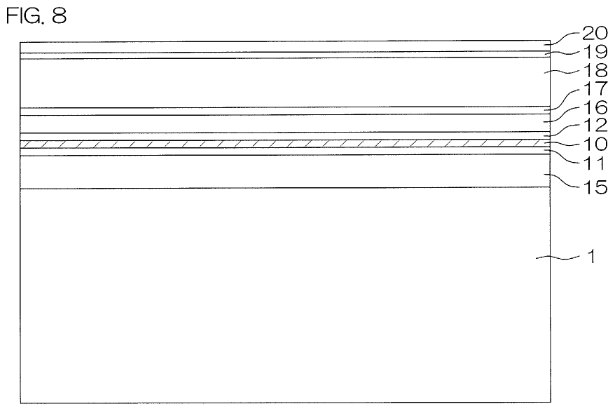

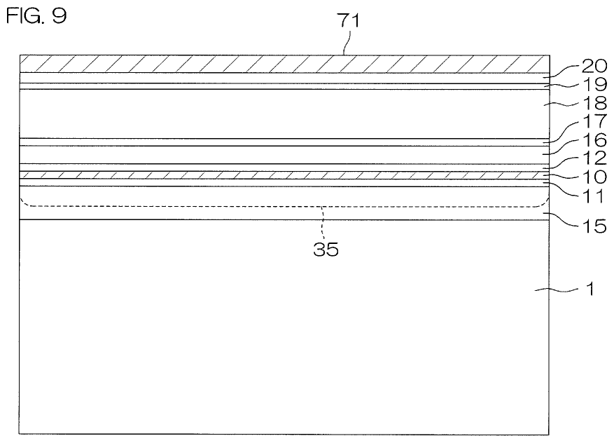

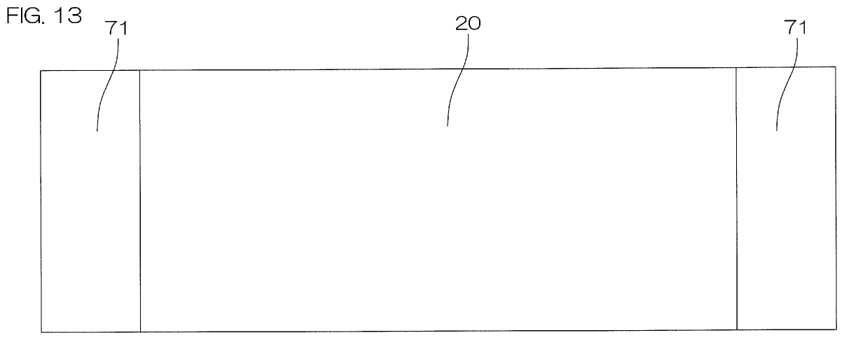

FIG. 8 to FIG. 13 are illustrative sectional views of a manufacturing process of the semiconductor laser element 60 shown in FIG. 1 to FIG. 6. Here, FIG. 8 and FIG. 10 to FIG. 12 are illustrative sectional views of a central portion corresponding to FIG. 6 and FIG. 9 is an illustrative sectional view of a vicinity of an end portion. FIG. 13 is a plan view.

First, as shown in FIG. 8, the n type AlGaAs cladding layer 15, the n side AlGaAs guide layer 11, the active layer 10, the p side AlGaAs guide layer 12, the first p type AlGaAs cladding layer 16, the p type InGaP etching stop layer 17, the second p type AlGaAs cladding layer 18, the p type InGaP etching stop layer 19, and the p type GaAs capping layer 20 are successively grown on the GaAs substrate 1 by metal organic chemical vapor deposition (MOCVD).

The active layer 10 is formed by repeatedly growing the barrier layers 222 constituted of the InAlGaAs layers and the quantum well layers 221 constituted of the GaAsP layers alternately in a plurality of cycles.

Next, as shown in FIG. 9 and FIG. 13, ZnO (zinc oxide) 71 is patterned on the p type GaAs capping layer 20 in regions corresponding to vicinities of the end surfaces of the semiconductor laser element 60. By then performing, for example, an annealing processing, Zn is diffused into the regions corresponding to the vicinities of the end surfaces of the semiconductor laser element 60. The end surface window structures 35 are thereby formed in the regions corresponding to the vicinities of the end surfaces of the semiconductor laser element 60.

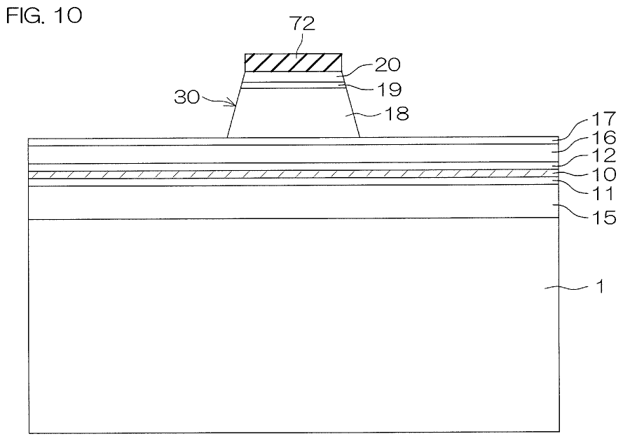

Next, the ZnO layer 71 is removed. Thereafter, as shown in FIG. 10, portions of the p type capping layer 20, the p type etching stop layer 19, and the second p type cladding layer 18 are removed by etching with an SiO₂ insulating film of stripe shape as a mask layer 72. The ridge stripe 30 on which the mask layer 72 is laminated on a top surface is thereby formed.

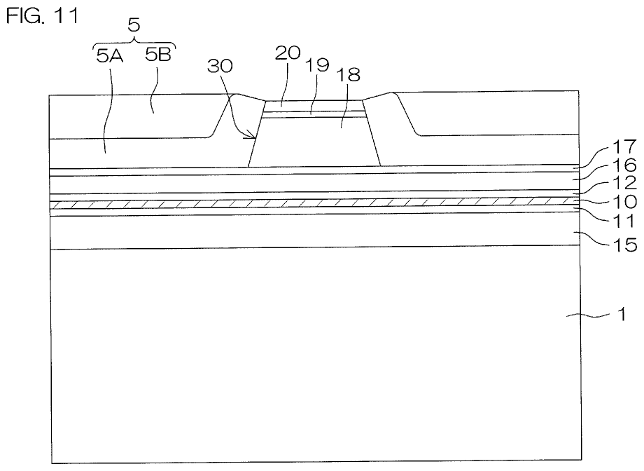

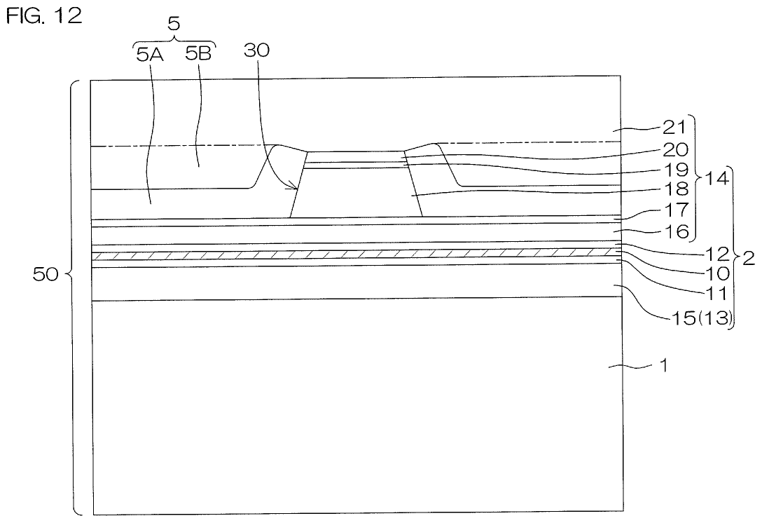

Next, after successively film-forming the lower layers 5A and the upper layers 5B of the current constriction layers 5 on the front surface as shown in FIG. 11, the mask layer 72 is removed. Then, as shown in FIG. 12, the p type contact layer 21 is grown on the front surface. Lastly, the p side electrode 4 that is in ohmic contact with the p type GaAs contact layer 21 is formed. Also, the n side electrode 3 that is in ohmic contact with the GaAs substrate 1 is formed.

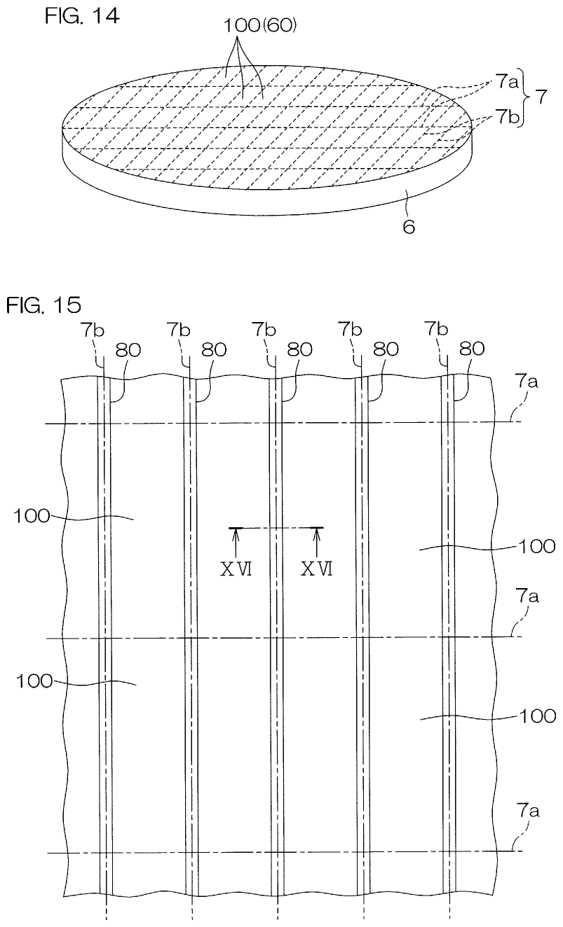

Although in FIG. 8 to FIG. 13, a manufacturing method for a single semiconductor laser element is illustrated, a wafer 6 in a state where a plurality of individual elements 100 (60) are formed is made as shown in FIG. 14 at the point at which the electrodes 3 and 4 are formed.

The respective individual elements 100 are formed in respective rectangular regions demarcated by virtual cutting lines 7 of a grid pattern on the wafer 6. The cutting lines 7 include end surface cutting lines 7a extending along a direction orthogonal to the long direction of the ridge stripes 30 (resonator length direction) and side surface cutting lines 7b extending along the long direction of the ridge stripes 30. The wafer 6 is divided into the respective individual elements 100 along such cutting lines 7. That is, the respective individual elements 100 are cut out by cleaving the wafer 6 along the cutting lines 7.

Next, a method for dividing the wafer 6 into the respective individual elements 100 shall be descried specifically.

As shown in FIG. 15, the first separating grooves (first dividing guide grooves) 80 extending along the side surface cutting lines 7b are formed by etching in the front surface of the semiconductor laminated structure 50. In FIG. 15, the n side electrode 3 and the p side electrode 4 are omitted.

A depth of the first separating grooves 80 is preferably a depth that reaches the substrate 1 upon penetrating through the current constriction layer 5, the p type semiconductor layer 14, the p type InGaP etching stop layer 17, the first p type AlGaAs cladding layer 16, the p side guide layer 12, the active layer 10, the n side guide layer 11, and the n type AlGaAs cladding layer 15.

FIG. 16A is a partially enlarged sectional view taken along line XVI-XVI of FIG. 15 and shows a cross-sectional shape of a first separating groove 80. As viewed from the resonator length direction, the first separating groove 80 has a pair of first tapered side surfaces 81 that gradually decrease in interval from each other toward a lower side from the front surface of the semiconductor laminated structure 50, a pair of second tapered side surfaces 82 that are connected to the tapered side surfaces 81 and gradually decrease in interval from each other toward the lower side, and a bottom surface 83 that couples lower edges of the pair of second tapered side surfaces 82 to each other. A gradient (inclination angle with respect to the front surface of the semiconductor laminated structure 50) of the second tapered side surfaces 82 is greater than a gradient of the first tapered side surfaces 81.

A depth D of the first separating groove 80 is approximately 12 μm. An interval W1 of the pair of first tapered side surfaces 81 at an opening portion of the first separating groove 80 is approximately 8 μm. An interval W2 of the pair of second tapered side surfaces 82 at a bottom surface portion of the first separating groove 80 is approximately 4 μm.

After the first separating grooves 80 are formed, the wafer 6 is cleaved along the end surface cutting lines 7a that are orthogonal to the resonator length direction. This shall be referred to as “primary cleavage.” As this primary cleavage, it suffices, for example, to form separating grooves (dividing guide grooves) extending along the end surface cutting lines 7a in a rear surface of the semiconductor laminated structure 50 and break the wafer 6 with the separating grooves as starting points. Besides laser processing, scribing by a diamond cutter, groove processing by a dicer, etc., can be applied to form the separating grooves extending along the end surface cutting lines 7a.

By this primary cleavage, a plurality of the bar bodies 110 shown in FIG. 17 are obtained. Both sides surface 111 of each bar body 110 are crystal surfaces that become the laser resonance surfaces 31 and 32. Reflecting films are formed on both side surfaces 111 of the bar body 110.

Next, as shown in FIG. 18, the second separating grooves (second dividing guide grooves) 90 that extend along length direction intermediate portions of the respective side surface cutting lines 7b are formed in a rear surface of each bar body 110. The second separating grooves 90 are not formed in regions of the rear surface of the bar body 110 that correspond to both end portions of the respective side surface cutting lines 7b. Besides laser processing, scribing by a diamond cutter, groove processing by a dicer, etc., can be applied to form the second separating grooves 90 that extend along the side surface cutting lines 7b.

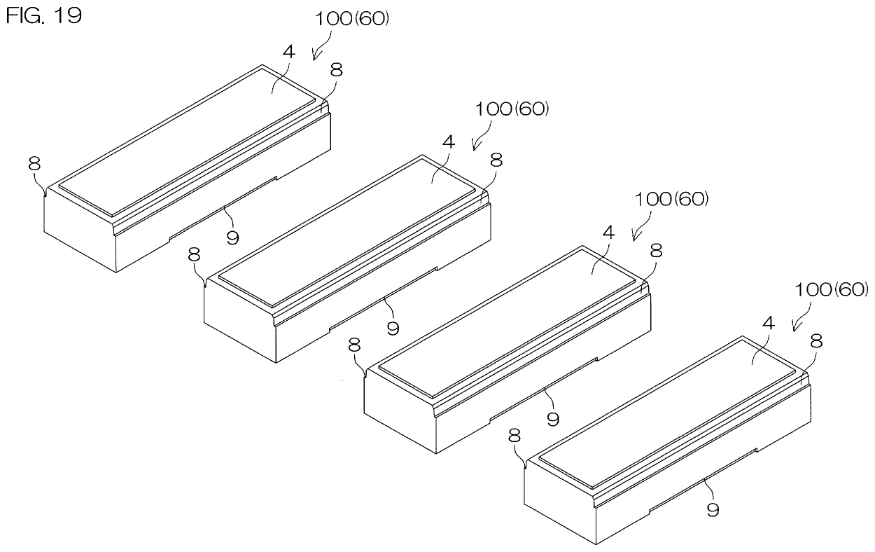

Blades (not shown) are then applied along the second separating grooves 90 from the rear surface side of the bar body 110 to apply external stresses to the bar body 110. Cracks are thereby formed from the first separating grooves 80 and the bar body 110 is cleaved along the side surface cutting lines 7b. This shall be referred to as “secondary cleavage.” By this secondary cleavage, the bar body 110 is divided according to each individual element 100 and a plurality of chips are obtained as shown in FIG. 19.

By the secondary cleavage, the first separating groove marks 8 are formed along the side surface cutting lines 7b in the upper edge regions of the side surfaces 33 and 34 of each individual element 100 and the second separating groove marks 9 are formed along the side surface cutting lines 7b in the length direction intermediate portions of the lower edge regions of the side surfaces 33 and 34 of the individual element 100.

Each first separating groove mark 8 has a shape (partial groove shape) with which the first separating groove 80 is divided in half along the long direction. Therefore, as shown in FIG. 2, the first separating groove mark 8 includes one side surface 81 of the pair of first tapered side surfaces 81 and one side surface 82 of the pair of second tapered side surfaces 82 of the first separating groove 80 and a portion 83a of the bottom surface 83 of the first separating groove 80. Each second separating groove mark 9 has a shape (partial groove shape) with which the second separating groove 90 is divided in half along the long direction.

With the first preferred embodiment described above, the quantum well layers 221 have the tensile strains for generating TM mode oscillation and therefore, the semiconductor laser element 60 can be made to oscillate in the TM mode.

Also, with the first preferred embodiment described above, the n type cladding layer 15 and the p type cladding layers 16 and 18 are respectively constituted of AlGaAs layers and therefore, serial resistance can be decreased in comparison to a semiconductor laser element with which an n type cladding layer and p type cladding layers are constituted of InGaAlP layers. Heat generation can thereby be suppressed in comparison to the semiconductor laser element with which the cladding layers are constituted of InGaAlP layers and therefore, a semiconductor laser element of high output power and high reliability can be obtained.

With respect to the semiconductor laser element 60 according to the first preferred embodiment described above, a semiconductor laser element with which the n type cladding layer 15 and the p type cladding layers 16 and 18 in the semiconductor laser element 60 shown in FIG. 1 are constituted of InGaAlP layers shall be deemed to be a comparative example.

The first preferred embodiment and the comparative example were respectively incorporated in packages. Optical output power vs. injection current characteristics at package temperatures of 25° C., 45° C., 65° C., and 85° C. were then measured with each of the first preferred embodiment and the comparative example. The package temperature was increased by heating the packages by a heating device.

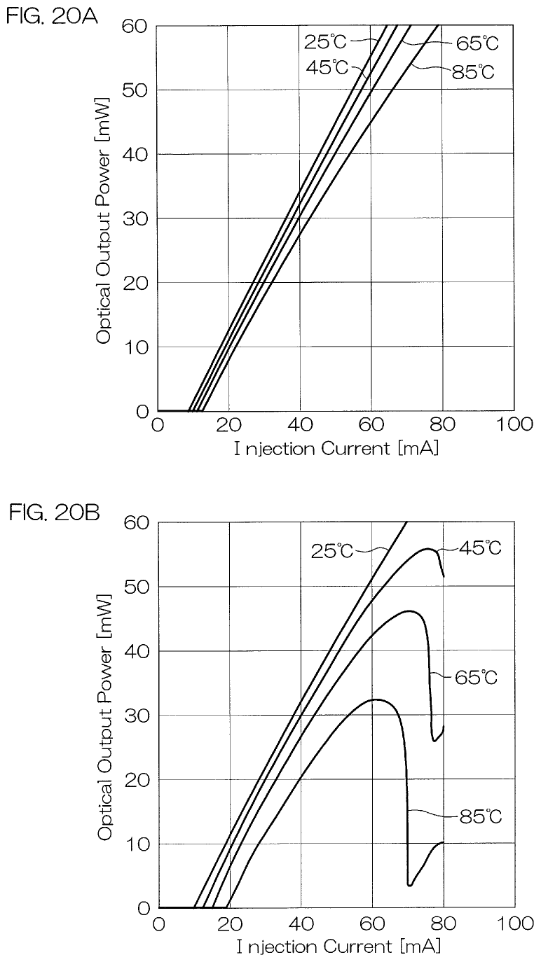

FIG. 20A is a graph of measurement results of the optical output power vs. injection current characteristics of the first preferred embodiment. FIG. 20B is a graph of measurement results of the optical output power vs. injection current characteristics of a comparative example.

As shown in FIG. 20B, with the comparative example, when the package temperature is 85° C., although the optical output power rises to approximately 33 mW with increase in the injection current, when 33 mW is exceeded, the optical output power decreases even when the injection current is increased. In other words, with the comparative example, when the package temperature is 85° C., the optical output power vs. injection current characteristics cannot maintain linearity when the optical output power exceeds approximately 33 mW.

On the other hand, as shown in FIG. 20A, with the first preferred embodiment, even when the package temperature is 85° C., the optical output power rises to approximately 60 mW with increase in the injection current. In other words, with the first preferred embodiment, when the package temperature is 85° C., the optical output power vs. injection current characteristics can maintain linearity to a range where the optical output power exceeds at least 50 mW. It can thus be understood that a semiconductor laser element of high output power and high reliability can be obtained with the first preferred embodiment.

Also, with the first preferred embodiment described above, the end surface window structures 35 that enlarge the bandgap of the active layer 10 are made at the laser resonator end surface portions and therefore, absorption of laser light at the laser resonator end surface portions can be suppressed. Catastrophic optical damage can thereby be suppressed and life extension of the semiconductor laser element can thus be achieved.

FIG. 16B is a sectional view of a modification example of the cross-sectional shape of the first separating groove 80 and is a partially enlarged sectional view corresponding to FIG. 16A. As viewed from the resonator length direction, this first separating groove 180 has a pair of tapered side surfaces 181 that gradually decrease in interval from each other toward a lower side from the front surface of the semiconductor laminated structure 50 and a bottom surface 182 that couples lower edges of the pair of tapered side surfaces 181 to each other.

A depth D of the first separating groove 180 is approximately 12 μm. An interval W1 of the pair of tapered side surfaces 181 at an opening portion of the first separating groove 180 is approximately 8 μm. An interval W2 of the tapered side surfaces 181 at a bottom surface portion of the first separating groove 180 is approximately 4 μm.

### [2] Second Embodiment

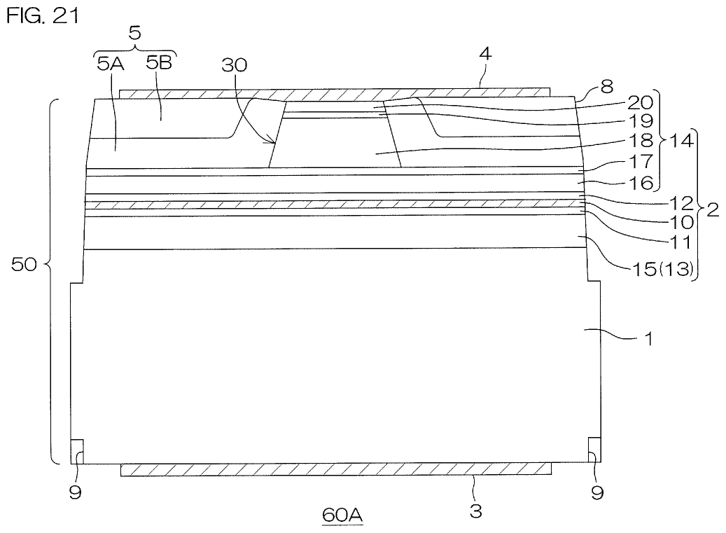

FIG. 21 is a sectional view of a semiconductor laser element according to a second preferred embodiment of the present invention and is a sectional view corresponding to the section plane of FIG. 6. In FIG. 21, portions corresponding to respective portions in FIG. 6 described above are indicated by attaching the same symbols as in FIG. 6.

In comparison to the semiconductor laser element 60 of FIG. 1 to FIG. 6, the present semiconductor laser element 60A differs just in the point that the p type contact layer 21 in the semiconductor laser element 60 is not provided. That is, this semiconductor laser element 60A has the p side electrode 4 formed on front surfaces of the capping layer 20 and the current constriction layers 5.

### [3] Third Embodiment

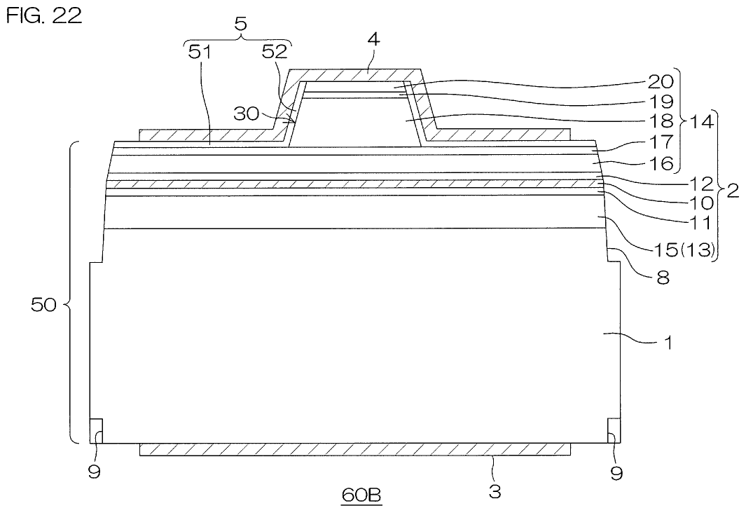

FIG. 22 is a sectional view of a semiconductor laser element according to a third preferred embodiment of the present invention and is a sectional view corresponding to the section plane of FIG. 6. In FIG. 22, portions corresponding to respective portions in FIG. 6 described above are indicated by attaching the same symbols as in FIG. 6.

In comparison to the semiconductor laser element 60 of FIG. 1 to FIG. 6, the p type contact layer 21 in the semiconductor laser element 60 is not provided in the present semiconductor laser element 60B. Further, with the semiconductor laser element 60B, the current constriction layers 5 differ from the current constriction layers 5 of the semiconductor laser element 60.

Each current constriction layer 5 is constituted of a first layer 51 oriented along a front surface of the p type InGaP etching stop layer 17 and a second portion 52 oriented along the side surfaces of the ridge 30. The current constriction layer 5 is constituted of an SiN layer and a thickness thereof is, for example, approximately 1000 Å to 2000 Å. The p side electrode 4 is formed on the front surfaces of the capping layer 20 and the current constriction layers 5.

### [4] Fourth Embodiment

Optical output power vs. current characteristics of a semiconductor laser element have a temperature dependence. Therefore, if a temperature of the semiconductor laser element varies, the optical output power varies. Also, an output wavelength of the semiconductor laser element has a temperature dependence. Therefore, if the temperature of the semiconductor laser element varies, the wavelength of output light varies.

An object of the fourth preferred embodiment is to provide a semiconductor laser element with which control of temperature of the semiconductor laser element is enabled.

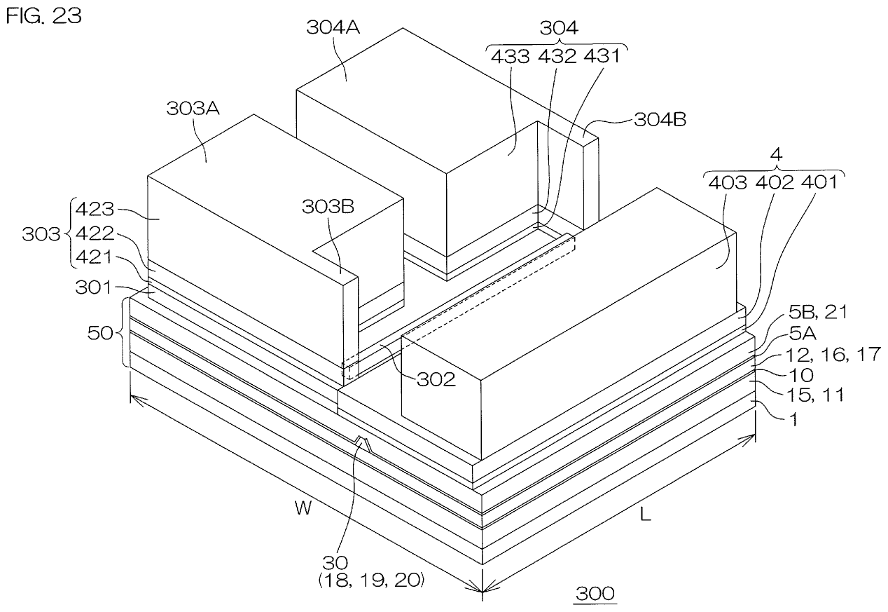

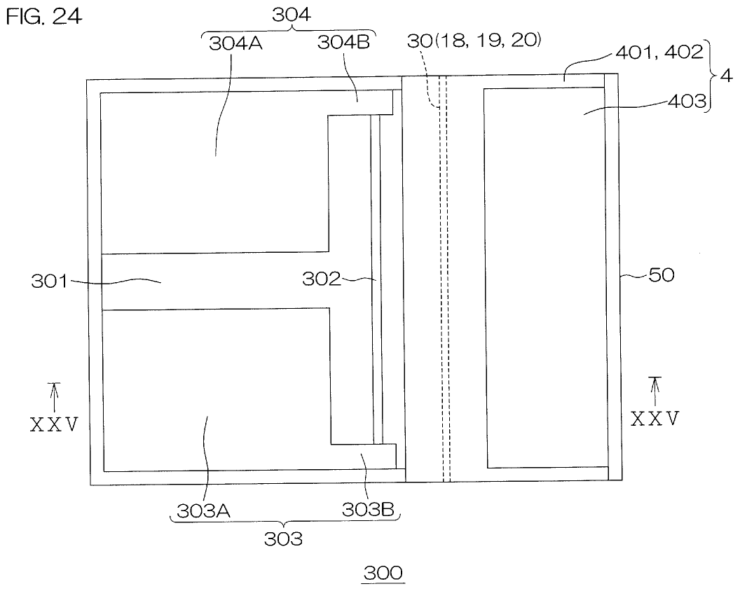

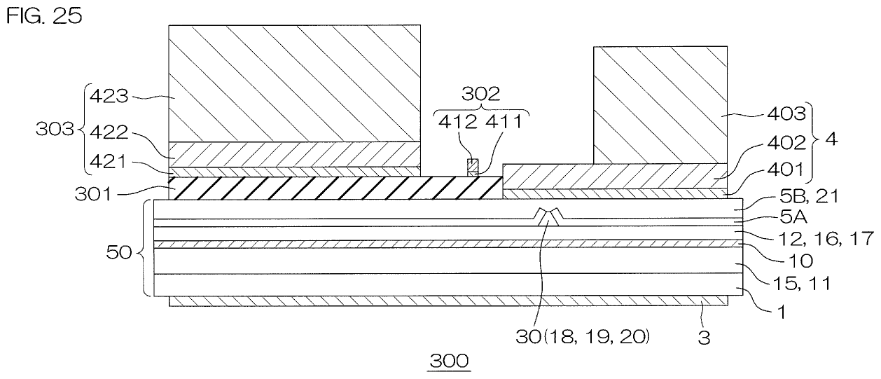

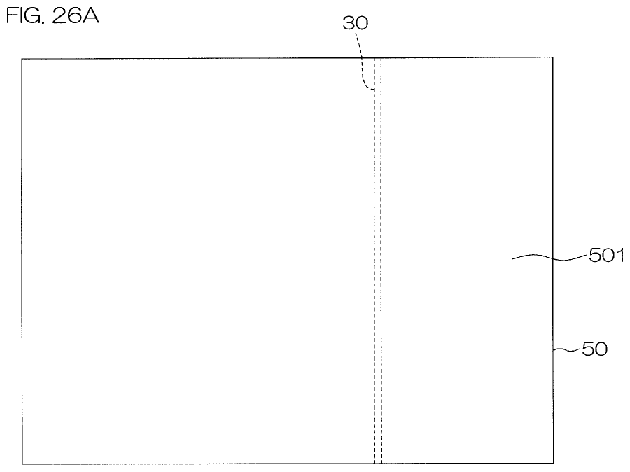

FIG. 23 is an illustrative perspective view of an outer appearance of a semiconductor laser element according to the fourth preferred embodiment of the present invention. FIG. 24 is an illustrative plan view of the semiconductor laser element of FIG. 23. FIG. 25 is an illustrative sectional view taken along line XXV-XXV of FIG. 24. In FIG. 25, portions corresponding to respective portions in FIG. 6 described above are indicated by attaching the same symbols as in FIG. 6.

The semiconductor laser element 300 includes the semiconductor laminated structure 50 of the same arrangement as the semiconductor laminated structure 50 in the broad sense of the semiconductor laser element 60 shown in FIG. 1 to FIG. 7. For convenience of description, the arrangement of the semiconductor laminated structure 50 is illustrated in simplified manner in FIG. 23 and FIG. 24. In the following description, a surface of the semiconductor laminated structure 50 at an opposite side to the substrate 1 shall be referred to as the front surface and a surface of the semiconductor laminated structure 50 at the substrate 1 side shall be referred to as the rear surface.

The semiconductor laser element 300 further includes the p side electrode 4 that is formed on a portion of the front surface of the semiconductor laminated structure 50 and the n side electrode 3 that is formed on substantially an entirety of the rear surface of the semiconductor laminated structure 50.

The semiconductor laser element 300 further includes an insulating film 301 that is formed on a portion of the front surface of the semiconductor laminated structure 50, a heater 302 that is formed on the insulating film 301, a first heater electrode 303 that is formed on the insulating film 301 and is connected to one end of the heater 302, and a second heater electrode 304 that is formed on the insulating film 301 and is connected to another end of the heater 302.

In FIG. 23 and FIG. 24, thicknesses of the p side electrode 4, the heater 302, the first heater electrode 303, and the second heater electrode 304 are drawn in exaggerated manner in comparison to a thickness of the semiconductor laminated structure 50.

In the following description, “forward,” “back,” “right,” and “left” shall respectively refer to a lower side of the sheet surface of FIG. 24, an upper side of the sheet surface of FIG. 24, a right side of the sheet surface of FIG. 24, and a left side of the sheet surface of FIG. 24.

The semiconductor laminated structure 50 has four edges of forward, back, right, and left in plan view and is of a rectangular shape that is long in a right-left direction. A length W in the right-left direction of the semiconductor laminated structure 50 is approximately 300 μm to 500 μm. A length L in a forward-back direction of the semiconductor laminated structure 50 is approximately 200 μm to 350 μm. The arrangement of the semiconductor laminated structure 50 is the same as the arrangement of the semiconductor laminated structure 50 of FIG. 6 and description thereof shall thus be omitted.

The ridge 30 extends in the forward-back direction. The ridge 30 is formed nearer to a right side than a right-left width center of the semiconductor laminated structure 50. As shown in FIG. 6, the ridge 30 includes the ridge portion (second p type cladding layer) 18 among the p type cladding layers 16 and 18, the p type etching stop layer 19, and the p type capping layer 20.

The p side electrode 4 is formed in a region of a right side portion of the front surface of the semiconductor laminated structure 50 such as to cover the ridge 30 in plan view. The p side electrode 4 is constituted of a first metal film 401 that is formed on the right side portion of the front surface of the semiconductor laminated structure 50, a second metal film 402 that is laminated on substantially an entirety of a front surface of the first metal film 401, and a third metal film 403 that is formed on substantially an entirety of a region of a second metal film 402 front surface excluding a left side portion.

The first metal film 401 is formed on an entirety of a region of the semiconductor laminated structure 50 front surface that extends from a position further to a left side than the ridge 30 by just a predetermined distance (for example, of approximately 10 μm to 50 μm) to a position further to the left side of the right edge of the semiconductor laminated structure 50 by just a predetermined distance (for example, of approximately 10 μm to 20 μm) in plan view. In this preferred embodiment, the first metal film 401 is constituted of Ti. The first metal film 401 is of a rectangular shape that is long in the forward-back direction in plan view. A length in the right-left direction of the first metal film 401 is approximately 100 μm to 180 μm. A length in the forward-back direction of the first metal film 401 is the same as the length L in the forward-back direction of the semiconductor laminated structure 50. A thickness of the first metal film 401 is approximately 0.05 μm to 0.2 μm.

In this preferred embodiment, the second metal film 402 is constituted of Au. The second metal film 402 is formed to the same rectangular shape as the first metal film 401 in plan view. A thickness of the second metal film 402 is approximately 0.1 μm to 0.3 μm.

In this preferred embodiment, the third metal film 403 is constituted of Au formed by a plating method. The third metal film 403 is of a rectangular shape that is long in the forward-back direction in plan view. A right-left direction length of the third metal film 403 is approximately 50 μm to 150 μm and is shorter than a right-left direction length of the second metal film 402. A forward-back direction length of the third metal film 403 is slightly shorter than a forward-back direction length of the second metal film 402. A right edge of the third metal film 403 coincides with a right edge of the second metal film 402 in plan view. A thickness of the third metal film 403 is approximately 1 μm to 5 μm.

The insulating film 301 is formed on a region, excluding peripheral edge portions of the semiconductor laminated structure 50, of a region of the front surface of the semiconductor laminated structure 50 further to the left side than the first metal film 401. The insulating film 301 is of a rectangular shape that is long in the forward-back direction. A right-left direction length of the insulating film 301 is approximately 150 μm to 350 μm. A forward-back direction length of the insulating film 301 is approximately 180 μm to 330 μm. A thickness of the insulating film 301 is approximately 0.1 μm to 0.3 μm. In this preferred embodiment, the insulating film 301 is constituted of SiN. The insulating film 301 may instead be SiO₂ or an epilayer doped to be of an N type.

The heater 302 is of a rectilinear shape that extends in parallel to the ridge 30 in plan view. The heater 302 is formed at a position further to the left side than a left edge of the first metal film 401 by just a predetermined distance (for example, of approximately 15 μm to 100 μm) in plan view. An interval between the heater 302 and the ridge 30 in plan view is approximately 10 μm to 70 μm. The heater 302 extends from near a forward edge of the insulating film 301 to near a back edge of the insulating film 301. A width of the heater 302 is approximately 5 μm to 20 μm.

The heater 302 is constituted of a laminated film of a Ti film 411 formed on the insulating film 301 and a Pt film 412 formed on the Ti film 411. A thickness of the Ti film 411 is approximately 0.05 μm to 0.2 μm. A thickness of the Pt film 412 is approximately 0.05 μm to 0.3 μm. Furthermore, a W film or a Mo film may be used in place of the Pt film 412.

The first heater electrode 303 is disposed inside a region of a forward side half of an insulating film 301 front surface. The first heater electrode 303 has an electrode portion (main portion) 303A and a connecting portion 303B formed integral to the electrode portion 303A. The electrode portion 303A is disposed at an opposite side to the p side electrode 4 with respect to the heater 302. The electrode portion 303A is of a rectangular shape that is long in the right-left direction in plan view. A forward-back direction length of the electrode portion 303A is approximately 100 μm to 150 μm and is slightly shorter than half the front-rear direction length of the insulating film 301. A right-left direction length of the electrode portion 303A is approximately 100 μm to 250 μm and is shorter than the right-left direction length of the insulating film 301. The electrode portion 303A is formed such that its forward edge coincides with the forward edge of the insulating film 301 and its left edge coincides with a left edge of the insulating film 301 in plan view. An interval between a right edge of the electrode portion 303A and the heater 302 is approximately 20 μm to 80 μm.

The connecting portion 303B extends rightward from a forward portion of the right edge of the electrode portion 303A. A tip of the connecting portion 303B extends to near the left edge of the first metal film 401 of the p side electrode 4. A length intermediate portion of the connecting portion 303B covers a forward end portion of the heater 302 and is mechanically and electrically connected to the forward end portion of the heater 302.

The electrode portion 303A and the connecting portion 303B of the first heater electrode 303 are constituted of a laminated film of a first metal film 421 formed on the insulating film 301 front surface, a second metal film 422 laminated on an entirety of a first metal film 421 front surface, and a third metal film 423 laminated on an entirety of a second metal film 422 front surface.

In this preferred embodiment, the first metal film 421 is constituted of Ti. A thickness of the first metal film 421 is approximately 0.05 μm to 0.3 μm. In this preferred embodiment, the second metal film 422 is constituted of Au. A thickness of the second metal film 422 is approximately 0.1 μm to 0.4 μm. In this preferred embodiment, the third metal film 423 is constituted of Au formed by a plating method. A thickness of the third metal film 423 is approximately 1 μm to 3 μm.

The second heater electrode 304 is disposed inside a region of a back side half of the insulating film 301 front surface. The second heater electrode 304 has an electrode portion (main portion) 304A and a connecting portion 304B formed integral to the electrode portion 304A. The electrode portion 304A is disposed at the opposite side to the p side electrode 4 with respect to the heater 302. The electrode portion 304A is of a rectangular shape that is long in the right-left direction in plan view. A forward-back direction length of the electrode portion 304A is approximately 100 μm to 150 μm and is slightly shorter than half the front-rear direction length of the insulating film 301. A right-left direction length of the electrode portion 304A is approximately 100 μm to 250 μm and is shorter than the right-left direction length of the insulating film 301. The electrode portion 304A is formed such that its back edge coincides with the back edge of the insulating film 301 and its left edge coincides with the left edge of the insulating film 301 in plan view. An interval between a right edge of the electrode portion 304A and the heater 302 is approximately 20 μm to 80 μm.

The connecting portion 304B extends rightward from a back portion of the right edge of the electrode portion 304A. A tip of the connecting portion 304B extends to near the left edge of the first metal film 401 of the p side electrode 4. A length intermediate portion of the connecting portion 304B covers a back end portion of the heater 302 and is mechanically and electrically connected to the back end portion of the heater 302.

The electrode portion 304A and the connecting portion 304B of the second heater electrode 304 are constituted of a laminated film of a first metal film 431 formed on the insulating film 301 front surface, a second metal film 432 laminated on an entirety of a first metal film 431 front surface, and a third metal film 433 laminated on an entirety of a second metal film 432 front surface.

In this preferred embodiment, the first metal film 431 is constituted of Ti. A thickness of the first metal film 431 is approximately 0.05 μm to 0.3 μm. In this preferred embodiment, the second metal film 432 is constituted of Au. A thickness of the second metal film 432 is approximately 0.1 μm to 0.4 μm. In this preferred embodiment, the third metal film 433 is constituted of Au formed by a plating method. A thickness of the third metal film 433 is approximately 1 μm to 5 μm.

Furthermore, the first heater electrode 303 and the second heater electrode 304 may be formed, for example, as follows. That is, the second heater electrode 304 is formed to an L shape in plan view that on the insulating film 301 extends along the back edge and the left edge of the insulating film 301 from above a back end portion of the heater 302. On the other hand, the first heater electrode 303 is formed in a region on the insulating film 301 surrounded by the heater 302 and the second heater electrode 304 such as to extend in the left direction from above a forward end portion of the heater 302 and thereafter toward the back.

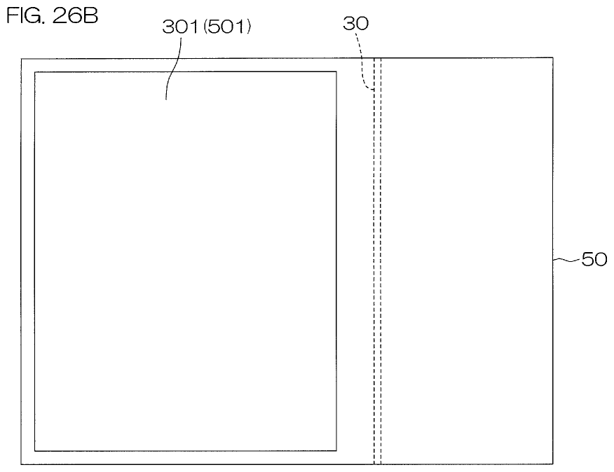

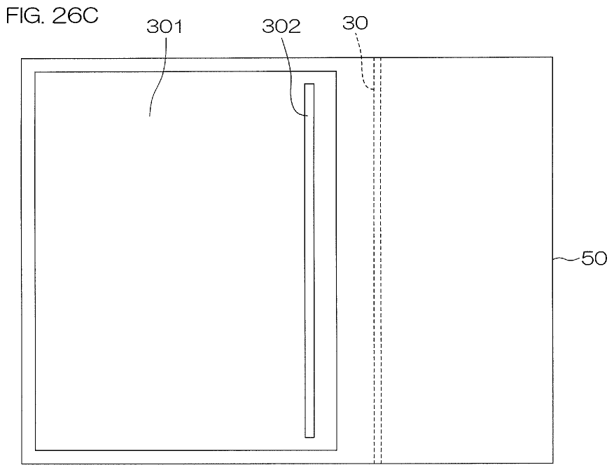

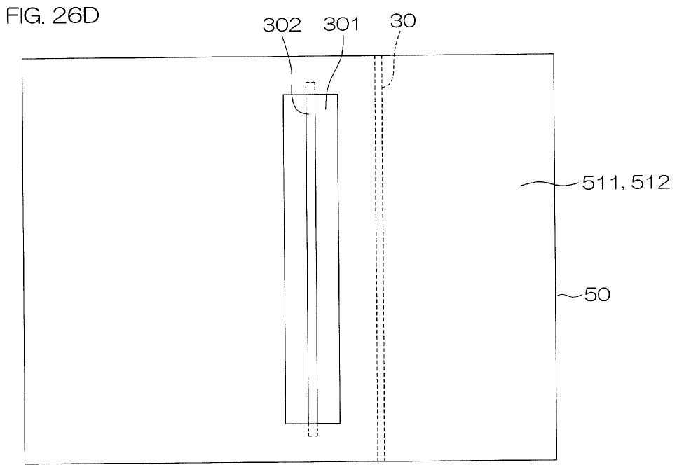

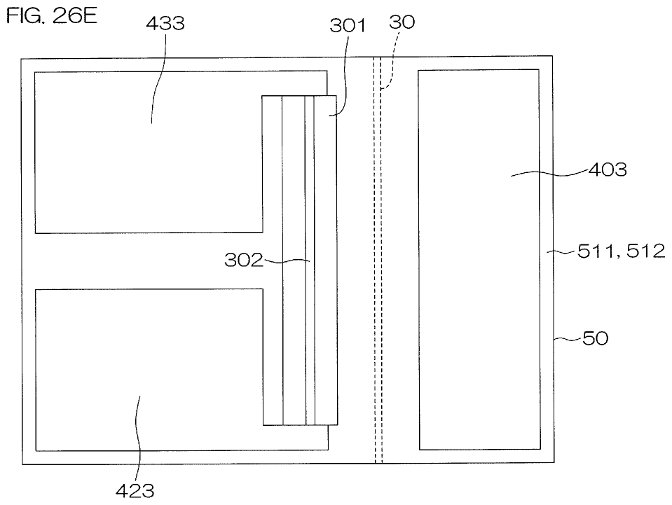

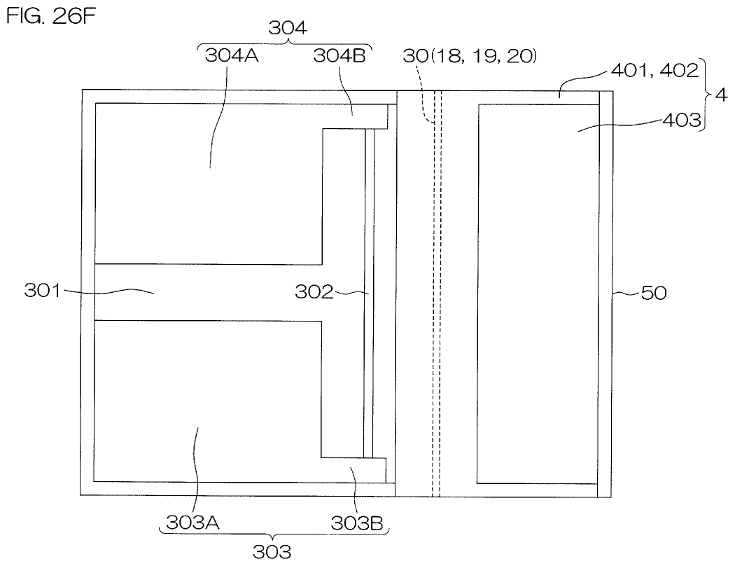

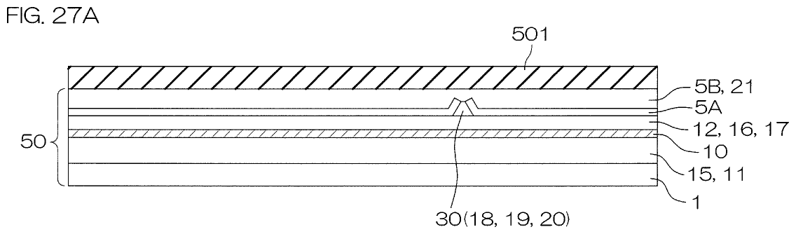

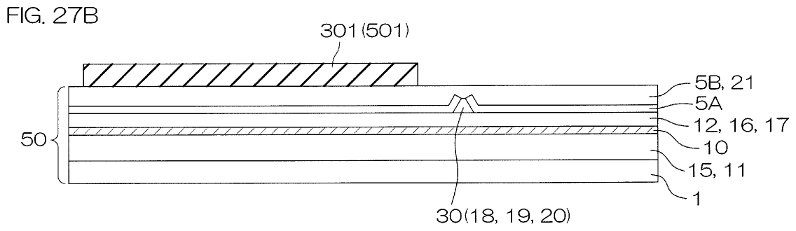

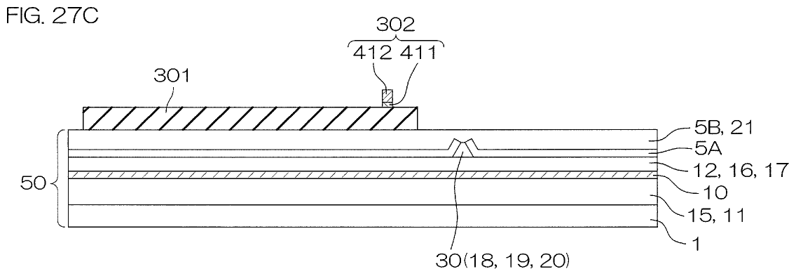

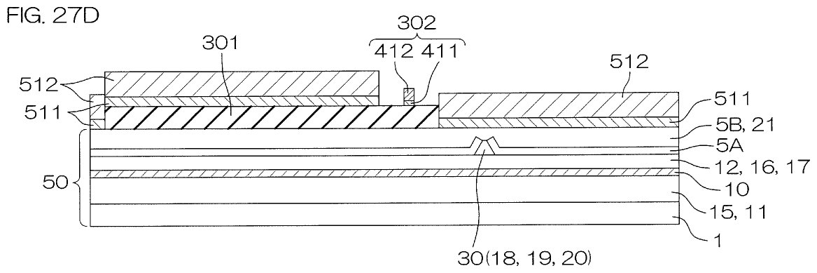

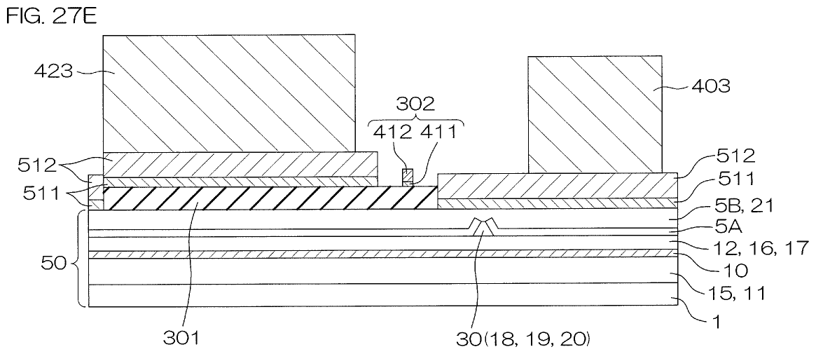

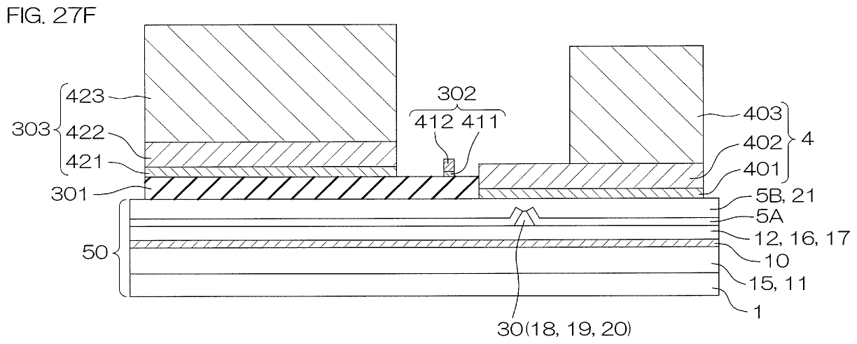

FIG. 26A to FIG. 26F are illustrative plan views of an example of a manufacturing process of the semiconductor laser element 300 described above. The plan views of FIG. 26A to FIG. 26F are plan views corresponding to the plan view of FIG. 24. FIG. 27A to FIG. 27F are illustrative sectional views of the example of the manufacturing process of the semiconductor laser element 300 described above. The sectional views of FIG. 27A to FIG. 27F are sectional views corresponding to the section plane of FIG. 25.

First, the semiconductor laminated structure 50 is prepared. Then, as shown in FIG. 26A and FIG. 27A, an insulating material film 501 that is a material film of the insulating film 301 is formed on an entirety of the front surface of the semiconductor laminated structure 50. With this embodiment, the insulating material film 501 is an SiN film. The insulating material film 501 may instead be SiO₂ or an epilayer doped to be of an N type.

Next, as shown in FIG. 26B and FIG. 27B, the insulating material film 501 is patterned by photolithography and etching. The insulating film 301 of rectangular shape in plan view is thereby formed on a region of the front surface of the semiconductor laminated structure 50 besides the right side portion and peripheral edge portions.

Next, as shown in FIG. 26C and FIG. 27C, the heater 302 extending in the forward-back direction is formed near a right edge of the insulating film 301 front surface by a vacuum deposition method. The heater 302 is constituted of the laminated film of the Ti film 411 formed on the insulating film 301 and the Pt film 412 formed on the Ti film 411.

Next, as shown in FIG. 26D and FIG. 27D, a first metal material film 511 that is a material film of the first metal films 401, 421, and 431 and a second metal material film 512 that is a material film of the second metal films 402, 422, and 432 are successively formed by a vacuum deposition method on an exposed surface of the semiconductor laminated structure 50 front surface and the front surface of the insulating film 301 while leaving intact a partial region. The partial region in which the first metal material film 511 and the second metal material film 512 are not formed is, in plan view, a rectangular region that, among regions on the insulating film 301, includes a length intermediate region, excluding both end portions, of the heater 302 and portions near both sides thereof. In this preferred embodiment, the first metal material film 511 is constituted of a Ti film and the second metal material film 512 is constituted of an Au film.

Next, as shown in FIGS. 26E and 27E, the third metal films 403, 423, and 433 are formed on the second metal material film 512 by a plating method.

Next, as shown in FIG. 26F and FIG. 27F, the first metal material film 511 and the second metal material film 512 are patterned. The first metal films 401, 421, and 431 constituted of the first metal material film 511 and the second metal films 402, 422, and 432 constituted of the second metal material film 512 are thereby obtained.

The p side electrode 4 that includes the first metal film 401, the second metal film 402, and the third metal film 403, the first heater electrode 303 that includes the first metal film 421, the second metal film 422, and the third metal film 423, and the second heater electrode 304 that includes the first metal film 431, the second metal film 432, and the third metal film 433 are thereby obtained. The first heater electrode 303 is constituted of the electrode portion 303A and the connecting portion 303B that is mechanically and electrically connected to the forward end of the heater 302. The second heater electrode 304 is constituted of the electrode portion 304A and the connecting porting 304B that is mechanically and electrically connected to the back end of the heater 302.

Lastly, by the n side electrode 3 being formed on the rear surface of the semiconductor laminated structure 50, the semiconductor laser element 300 shown in FIG. 23 to FIG. 25 is obtained.

With the semiconductor laser element 300 described above, the heater 302 is included and therefore, by driving and controlling the heater 302, a temperature of the semiconductor laser element 300 can be controlled.

For example, by performing on/off control of the heater 302 as follows, the temperature of the semiconductor laser element 300 can be controlled such that the temperature of the semiconductor laser element 300 is substantially fixed.

In a case where the semiconductor laser element 300 is controlled such as to be on and off repeatedly, the heater 302 is turned on to heat the semiconductor laser element 300 for a predetermined time before the semiconductor laser element 300 is turned on for the first time. Then, when the semiconductor laser element 300 is turned on, the heater 302 is turned off. Thereafter, the heater 302 is turned on when the semiconductor laser element 300 is turned off and the heater 302 is turned off when the semiconductor laser element 300 is turned on.

Also, the temperature of the semiconductor laser element 300 may be detected and the heater 302 may be on/off controlled such that the temperature of the semiconductor laser element 300 is within a predetermined temperature range.

Also, with the semiconductor laser element 300, the electrode portion (main portion) 303A of the first heater electrode 303 and the electrode portion (main portion) 304A of the second heater electrode 304 are respectively disposed at the opposite side to the p side electrode 4 with respect to the heater 302. Also, the electrode portion 303A of the first heater electrode 303, the electrode portion 304A of the second heater electrode 304, and the p side electrode 4 respectively have portions that are thicker than a thickness of the heater 302.

Specifically, in this preferred embodiment, whereas the thickness of the heater 302 is 0.15 μm, a thickness of the portion of the p side electrode 4 at which the third metal film 403 is formed, a thickness of the first heater electrode 303, and a thickness of the second heater electrode 304 are 1.30 μm each. Therefore, flawing of the heater 302 by contacting it when handling the semiconductor laser element 300 can be suppressed. Degradation of the heater 302 can thereby be suppressed. From such a standpoint, the electrode portion 303A of the first heater electrode 303, the electrode portion 304A of the second heater electrode 304, and the p side electrode 4 preferably include portions having a thickness of not less than 5 times the thickness of the heater 302.

Also, the arrangement of the semiconductor laminated structure 50 of the semiconductor laser element 300 is the same as the arrangement of the semiconductor laminated structure 50 of the semiconductor laser element 60 according to the first preferred embodiment and therefore, the semiconductor laser element 300 exhibits the same effects as the semiconductor laser element 60 according to the first preferred embodiment.

Further, the semiconductor laminated structure 50 of the semiconductor laser element 300 may be the same in arrangement as the semiconductor laminated structure 50 of the semiconductor laser element 60A of FIG. 21 or the semiconductor laminated structure 50 of the semiconductor laser element 60B of FIG. 22.

Also, the semiconductor laminated structure 50 of the semiconductor laser element 300 may be of an arrangement other than the arrangements described above as long as it is an arrangement capable of outputting semiconductor laser light. The semiconductor laminated structure 50 of the semiconductor laser element 300 is not restricted to an arrangement that generates polarized light of the TM mode but may be of an arrangement that generates polarized light of TE mode instead.

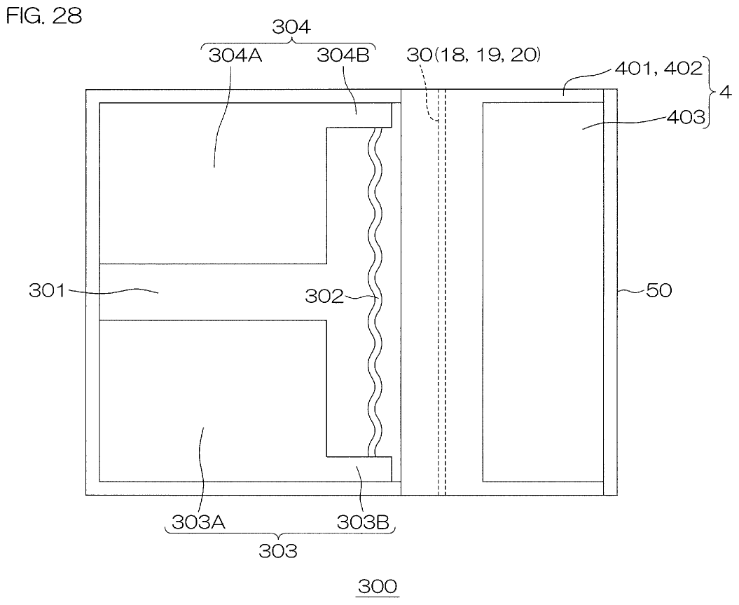

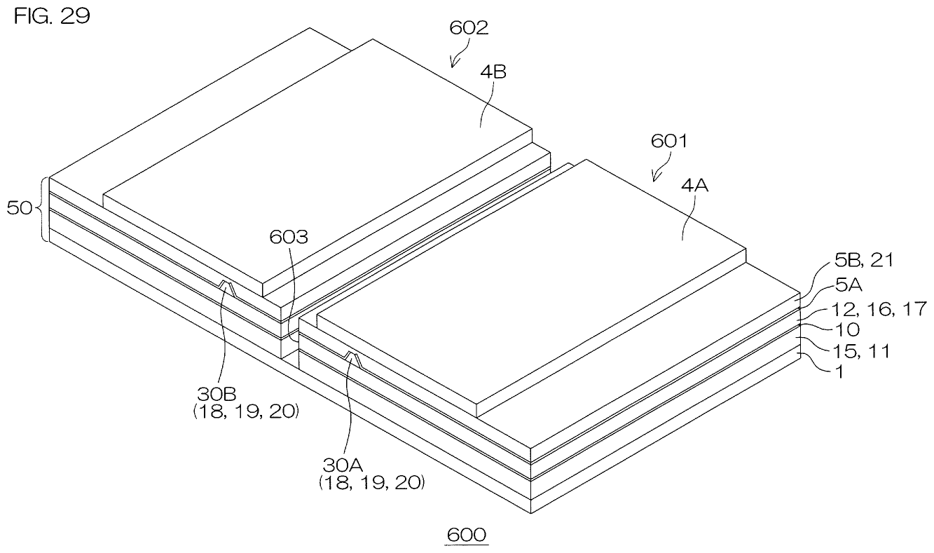

Although with the semiconductor laser element 300 according to the fourth preferred embodiment described above, the heater 302 is of a rectilinear shape, the heater 302 may instead have a meandering shape in plan view as shown in FIG. 28.

### [5] Fifth Embodiment

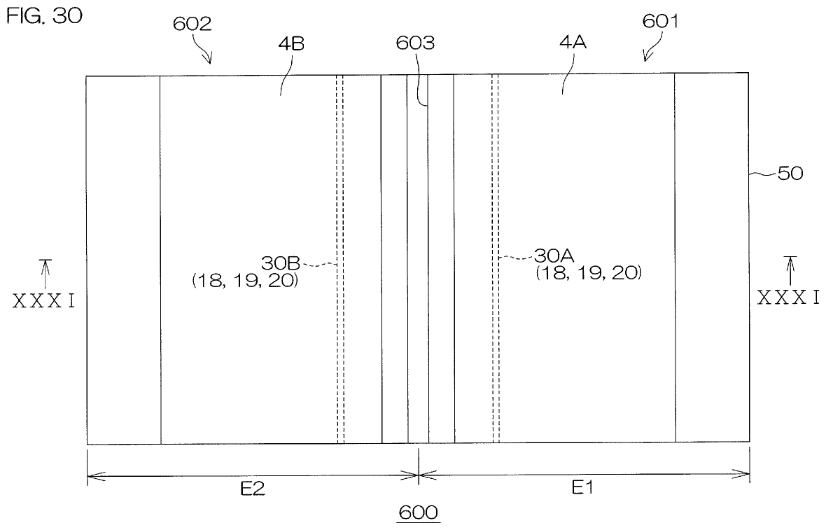

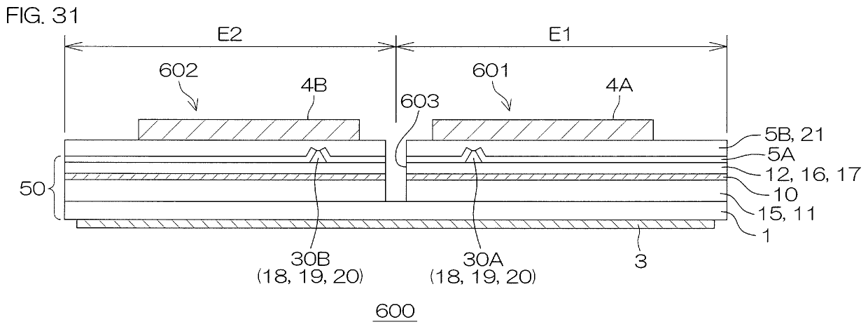

FIG. 29 is an illustrative perspective view of an outer appearance of a semiconductor laser element according to a fifth preferred embodiment of the present invention. FIG. 30 is an illustrative plan view of the semiconductor laser element of FIG. 29. FIG. 31 is an illustrative sectional view taken along line XXXI-XXXI of FIG. 30. In FIG. 31, portions corresponding to respective portions in FIG. 6 described above are indicated by attaching the same symbols as in FIG. 6.

The semiconductor laser element 600 includes the semiconductor laminated structure 50 of the same arrangement as the semiconductor laminated structure 50 in the broad sense of the semiconductor laser element 60 shown in FIG. 1 to FIG. 7. For convenience of description, the arrangement of the semiconductor laminated structure 50 is illustrated in simplified manner in FIG. 29 and FIG. 31. In the following description, a surface of the semiconductor laminated structure 50 at an opposite side to the substrate 1 shall be referred to as the front surface and a surface of the semiconductor laminated structure 50 at the substrate 1 side shall be referred to as the rear surface.

In the following description, “forward,” “back,” “right,” and “left” shall respectively refer to a lower side of the sheet surface of FIG. 30, an upper side of the sheet surface of FIG. 30, a right side of the sheet surface of FIG. 30, and a left side of the sheet surface of FIG. 30.

The semiconductor laminated structure 50 has four edges of forward, back, right, and left in plan view and is of a rectangular shape that is long in a right-left direction. A region separating groove 603 that separates a main semiconductor laser region E1 of substantially a right half portion and a heat source semiconductor laser region E2 of substantially a left half portion is formed at a width central portion of the front surface of the semiconductor laminated structure 50. The region separating groove 603 traverses the front surface of the semiconductor laminated structure 50 in a forward-back direction in plan view. The region separating groove 603 reaches the substrate 1 inside the semiconductor laminated structure 50. The main semiconductor laser region E1 is used as a main semiconductor laser 601 and the heat source semiconductor laser region E2 is used as a heat source semiconductor laser 602.

In this semiconductor laser element 600, the ridge 30 is formed in each of the main semiconductor laser region E1 and the heat source semiconductor laser region E2. In the following description, the ridge 30 formed in the main semiconductor laser region E1 shall be referred to as the first ridge 30A and the ridge 30 formed in the heat source semiconductor laser region E2 shall be referred to as the second ridge 30B. Each of the ridges 30A and 30B includes the ridge portion (second p type cladding layer) 18 among the p type cladding layers 16 and 18, the p type etching stop layer 19, and the p type capping layer 20 as shown in FIG. 6.

In the main semiconductor laser region E1, a portion of the semiconductor laminated structure 50 at an upper side of the substrate 1 (the semiconductor laminated structure 2 in the narrow sense) is rectangular in plan view.

In the main semiconductor laser region E1, the first ridge 30A extends in the forward-back direction. The first ridge 30A is formed nearer to a left side than a center in the right-left direction (width center) of the main semiconductor laser region E1. The first ridge 30A includes, in a lowermost layer, the ridge portion (first ridge portion) 18 among the p type cladding layers 16 and 18.

In the main semiconductor laser region E1, a first p side electrode 4A for the main semiconductor laser 601 is formed on the front surface of the semiconductor laminated structure 50. The first p side electrode 4A is, for example, constituted of a Ti film that is formed on the front surface of the semiconductor laminated structure 50, a first Au film that is laminated on the Ti film, and a second Au film that is laminated on the first Au film. The Ti film and the first Au film are formed, for example, by a vacuum deposition method, and the second Au film is formed, for example, by a plating method.

In the heat source semiconductor laser region E2, a portion of the semiconductor laminated structure 50 at an upper side of the substrate 1 (the semiconductor laminated structure 2 in the narrow sense) is rectangular in plan view.

In the heat source semiconductor laser region E2, the second ridge 30B extends in the forward-back direction. The second ridge 30B is formed nearer to a right side than a center in the right-left direction (width center) of the heat source semiconductor laser region E2. The second ridge 30B includes, in a lowermost layer, the ridge portion (second ridge portion) 18 among the p type cladding layers 16 and 18.

In the heat source semiconductor laser region E2, a second p side electrode 4B for the heat source semiconductor laser 602 is formed on the front surface of the semiconductor laminated structure 50. The second p side electrode 4B is, for example, constituted of a Ti film that is formed on the front surface of the semiconductor laminated structure 50, a first Au film that is laminated on the Ti film, and a second Au film that is laminated on the first Au film. The Ti film and the first Au film are formed, for example, by a vacuum deposition method, and the second Au film is formed, for example, by a plating method.

The n side electrode 3 is formed on the rear surface of the semiconductor laminated structure 50 such as to span across the main semiconductor laser region E1 and the heat source semiconductor laser region E2. The n side electrode 3 is an n side electrode in common to the main semiconductor laser 601 and the heat source semiconductor laser 602.

That is, the semiconductor laser element 600 includes the main semiconductor laser 601 and the heat source semiconductor laser 602 that is disposed adjacent to the main semiconductor laser 601. The main semiconductor laser 601 is constituted of a portion of the semiconductor laminated structure 50 corresponding to the main semiconductor laser region E1, the first p side electrode 4A, and the n side electrode 3. The heat source semiconductor laser 602 is constituted of a portion of the semiconductor laminated structure 50 corresponding to the heat source semiconductor laser region E2, the second p side electrode 4B, and the n side electrode 3. The main semiconductor laser 601 and the heat source semiconductor laser 602 have the substrate 1 in common.

The main semiconductor laser 601 is used as a semiconductor laser. The heat source semiconductor laser 602 is used as a heat source arranged to control a temperature of the main semiconductor laser 601. This heat source makes use of the fact that when a semiconductor laser is driven, energy that is not photoconverted is converted to heat.

Such a semiconductor laser element 600 is manufactured, for example, as follows. First, the semiconductor laminated structure 50 having the first ridge portion 30A and the second ridge portion 30B is prepared. Next, the first p side electrode 4A and the second p side electrode 4B are formed on the front surface of the semiconductor laminated structure 50. Next, the region separating groove 603 that is arranged to separate the main semiconductor laser region E1 and the heat source semiconductor laser region E2 is formed in the front surface of the semiconductor laminated structure 50. Lastly, the n side electrode 3 is formed on the rear surface of the semiconductor laminated structure 50.

The semiconductor laser element 600 described above includes the main semiconductor laser 601 and the heat source semiconductor laser 602 and therefore, by driving and controlling the heat source semiconductor laser 602, the temperature of the main semiconductor laser 601 (semiconductor laser element 600) can be controlled.

For example, by performing on/off control of the heat source semiconductor laser 602 as follows, the temperature of the semiconductor laser element 600 can be controlled such that the temperature of the semiconductor laser element 600 (main semiconductor laser 601) is substantially fixed.

In a case where the main semiconductor laser 601 is controlled such as to be on and off repeatedly, the heat source semiconductor laser 602 is turned on to heat the main semiconductor laser 601 for a predetermined time before the main semiconductor laser 601 is turned on for the first time. Then, when the main semiconductor laser 601 is turned on, the heat source semiconductor laser 602 is turned off. Thereafter, the heat source semiconductor laser 602 is turned on when the main semiconductor laser 601 is turned off and the heat source semiconductor laser 602 is turned off when the main semiconductor laser 601 is turned on.

Also, the temperature of the main semiconductor laser 601 may be detected and the heat source semiconductor laser 602 may be on/off controlled such that the temperature of the main semiconductor laser 601 is within a predetermined temperature range.

Also, the arrangement of the semiconductor laminated structure 50 of the semiconductor laser element 600 is the same as the arrangement of the semiconductor laminated structure 50 of the semiconductor laser element 60 according to the first preferred embodiment and therefore, the semiconductor laser element 600 exhibits the same effects as the semiconductor laser element 60 according to the first preferred embodiment.

Further, the semiconductor laminated structure 50 of the semiconductor laser element 600 may be the same in arrangement as the semiconductor laminated structure 50 of the semiconductor laser element 60A of FIG. 21 or the semiconductor laminated structure 50 of the semiconductor laser element 60B of FIG. 22.

Also, the semiconductor laminated structure 50 of the semiconductor laser element 600 may be of an arrangement other than the arrangements described above as long as it is an arrangement capable of outputting semiconductor laser light. The semiconductor laminated structure 50 of the semiconductor laser element 600 is not restricted to an arrangement that generates polarized light of the TM mode but may be of an arrangement that generates polarized light of TE mode instead.

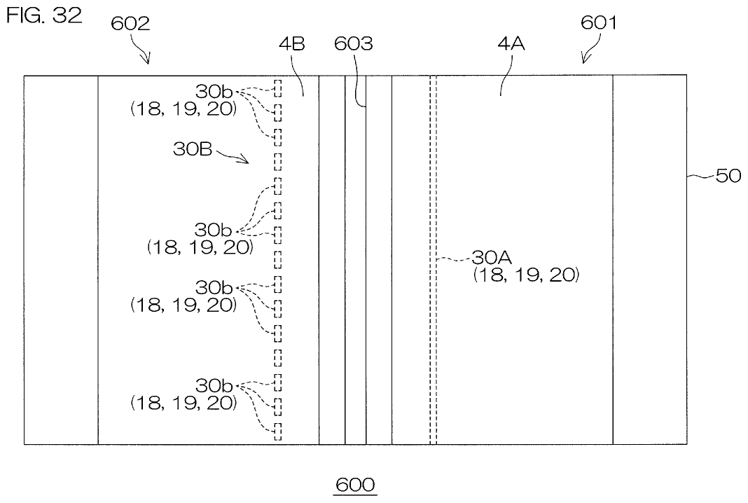

Although with the semiconductor laser element 600 according to the fifth preferred embodiment described above, the ridge 30 (second ridge 30B) formed in the heat source semiconductor laser region E2 is of a rectilinear shape, the second ridge 30B may be constituted of a plurality of rectangular ridges 30b that are disposed rectilinearly at intervals in plan view as shown in FIG. 32. Further, each rectangular ridge 30b includes, in a lowermost layer, a rectangular ridge portion constituted of the first p type cladding layer 18.

While preferred embodiments of the present invention have been described in detail, these are merely specific examples used to clarify the technical contents of the present invention and the present invention should not be interpreted as being limited to these specific examples and the scope of the present invention is to be limited only by the appended claims.

The present application corresponds to Japanese Patent Application No. 2018-248029 filed on Dec. 28, 2018 in the Japan Patent Office and Japanese Patent Application No. 2019-026821 filed on Feb. 18, 2019 in the Japan Patent Office, and the entire disclosures of these applications are incorporated herein by reference.

### REFERENCE SIGNS LIST

1 substrate

2 semiconductor laminated structure (narrow sense)

3 n side electrode

4, 4A, 4B p side electrode

5 current constriction layer

6 wafer

7 cutting line

7a end surface cutting line

7b side surface cutting line

8 first separating groove mark

9 second separating groove mark

10 active layer

11 n side guide layer

12 p side guide layer

13 n type semiconductor layer

14 p type semiconductor layer

15 n type AlGaAs cladding layer

16 first p type AlGaAs cladding layer

17 p type InGaP etching stop layer

18 second p type AlGaAs cladding layer

19 p type InGaP etching stop layer

20 p type GaAs capping layer

21 p type contact layer

30, 30A, 30B ridge

30b rectangular ridge

31, 32 resonator end surface

33, 34 side surface

35 side surface window structure

41 first electrode film

42 second electrode film

50 semiconductor laminated structure (broad sense)

60 semiconductor laser element

71 ZnO layer

72 mask layer

80 first separating groove

81 first tapered side surface

82 second tapered side surface

83 bottom surface

90 second separating groove

100 individual element

110 bar body

221 quantum well layer

222 barrier layer

300, 600 semiconductor laser element

301 insulating film

302 heater

303 first heater electrode

303A electrode portion

303B connecting portion

304 second heater electrode

304A electrode portion

304B connecting portion

401, 421, 431 first metal film

402, 422, 432 second metal film

403, 423, 433 third metal film

411 Ti film

412 Pt film

501 insulating material film

512 first metal material film

601 main semiconductor laser

602 heat source semiconductor laser

603 region separating groove

1. A semiconductor laser element being a semiconductor laser element that oscillates in TM mode and comprising:
a semiconductor laminated structure that has a substrate, an n type cladding layer disposed at a front surface side of the substrate, an active layer disposed at an opposite side to the substrate with respect to the n type cladding layer, and a p type cladding layer disposed at an opposite side to the n type cladding layer with respect to the active layer; and
wherein the active layer includes a quantum well layer having a tensile strain for generating TM mode oscillation and
the n type cladding layer and the p type cladding layer are respectively constituted of AlGaAs layers.

2. The semiconductor laser element according to claim 1, wherein an end surface window structure that enlarges a bandgap of the active layer is formed at an end surface portion of a laser resonator.

3. The semiconductor laser element according to claim 1, wherein the active layer includes
a plurality of the quantum well layers and
a barrier layer sandwiched by the quantum well layers that are adjacent and having a compressive strain.

4. The semiconductor laser element according to claim 3, wherein the substrate is constituted of a GaAs substrate and
the quantum well layer is constituted of a GaAsP layer.

5. The semiconductor laser element according to claim 3, wherein the substrate is constituted of a GaAs substrate and
the barrier layer is constituted of an InAlGaAs layer.

6. The semiconductor laser element according to claim 1, further comprising: a current constriction layer that is formed at an opposite side to the active layer with respect to the p type cladding layer and is arranged to constrict current flowing through the active layer.

7. The semiconductor laser element according to claim 6, wherein a front surface of the p type cladding layer at an opposite side to the active layer as viewed in a resonator length direction includes a flat portion that is parallel to a front surface of the active layer and inclined surfaces that are respectively formed at both sides of the flat portion and are inclined with respect to the front surface of the active layer,
a p type GaAs capping layer is formed on the flat portion of the p type cladding layer, and
the current constriction layer is formed such as to cover the inclined surfaces of the p type cladding layer and a side surface of the p type GaAs capping layer.

8. The semiconductor laser element according to claim 7, wherein the current constriction layer is constituted of a laminated film of an AlGaAs layer and a GaAs layer formed on the AlGaAs layer.

9. The semiconductor laser element according to claim 7, comprising: a GaAs contact layer that is formed such as to cover a front surface of the current constricting layer and a front surface of the p type GaAs capping layer;
a p side electrode that is formed on the GaAs contact layer; and an N side electrode that is formed on a rear surface of the substrate.

10. The semiconductor laser element according to claim 1, wherein the semiconductor laminated structure has a pair of end surfaces that constitute resonance surfaces of the laser resonator, a pair of side surfaces, and first separating groove marks that are formed in upper edge regions of the pair of side surfaces continuous to a front surface of the semiconductor laminated structure.

11. The semiconductor laser element according to claim 10, wherein the first separating groove marks are formed across an entire length direction of the semiconductor laminated structure.

12. The semiconductor laser element according to claim 10, wherein the semiconductor laminated structure further has second separating groove marks that are formed in lower edge regions of the pair of side surfaces that are continuous to a rear surface of the semiconductor laminated structure.

13. The semiconductor laser element according to claim 12, wherein the second separating groove marks are formed in length direction intermediate portions of the semiconductor laminated structure.

14. The semiconductor laser element according to claim 1, comprising: a semiconductor laser p side electrode that is formed on portion of a front surface of the semiconductor laminated structure at an opposite side to the substrate side;
an insulating film that is formed on a portion of the front surface of the semiconductor laminated structure;
a heater that is formed on the insulating film; and
a first heater electrode connected to one end of the heater and a second heater electrode connected to another end of the heater that are formed on the insulating film.

15. The semiconductor laser element according to claim 14, wherein a main portion of the first heater electrode and a main portion of the second heater electrode are each disposed at an opposite side to the semiconductor laser p side electrode with respect to the heater and
the main portion of the first heater electrode, the main portion of the second heater electrode, and the semiconductor laser p side electrode respectively have portions thicker than a thickness of the heater.

16. The semiconductor laser element according to claim 15, wherein the portions thicker than the thickness of the heater each have a thickness not less than 5 times the thickness of the heater.

17. The semiconductor laser element according to claim 14, wherein the p type cladding layer has a ridge portion of rectilinear shape and
the semiconductor laser p side electrode is formed in a region that includes the ridge portion in plan view.

18. The semiconductor laser element according to claim 17, wherein the heater is disposed in parallel to the ridge portion in plan view.

19. The semiconductor laser element according to claim 18, wherein the heater extends rectilinearly in plan view.

20. The semiconductor laser element according to claim 18, wherein the heater extends in a meandering shape in plan view.

21. The semiconductor laser element according to claim 14, wherein the heater is constituted of a laminated film of a Ti film formed on the insulating film and a Pt film laminated on the Ti film.

22. The semiconductor laser element according to claim 1, wherein a region separating groove that separates a main semiconductor laser region used as a main semiconductor laser and a heat source semiconductor laser region used as a heat source semiconductor laser is formed on a front surface of the semiconductor laminated structure at an opposite side to the substrate side,
a first p side electrode for the main semiconductor laser is formed on the front surface of the semiconductor laminated structure in the main semiconductor laser region, and
a second p side electrode for the heat source semiconductor laser is formed on the front surface of the semiconductor laminated structure in the heat source semiconductor laser region.

23. The semiconductor laser element according to claim 22, wherein the region separating groove reaches the substrate.

24. The semiconductor laser element according to claim 22, wherein an n side electrode for the main semiconductor laser and the heat source semiconductor laser is formed on a rear surface of the semiconductor laminated structure at an opposite side to the front surface.

25. The semiconductor laser element according to claim 22, wherein, in the main semiconductor laser region, the p type cladding layer has a first ridge portion of rectilinear shape and
in the heat source semiconductor laser region, the p type cladding layer has a second ridge portion of rectilinear shape.

26. The semiconductor laser element according to claim 25, wherein the second ridge portion is constituted of a plurality of rectangular ridge portions that are disposed rectilinearly at intervals in plan view.
